(19) United States
(12) Patent Application Publication
(10) Pub. No.: US 2024/0387255 A1
(43) Pub. Date: Nov. 21, 2024

(54) DEVICE AND METHOD OF FORMING THE SAME

(71) Applicant: Taiwan Semiconductor Manufacturing Co., Ltd., Hsinchu (TW)

(72) Inventors: Yu-Lien Huang, Jhubei (TW); Yi-Nien Su, Hsinchu (TW); Huang-Ming Chen, Hsinchu (TW)

(21) Appl. No.: 18/789,252

(22) Filed: Jul. 30, 2024

Related U.S. Application Data
(62) Division of application No. 17/651,615, filed on Feb. 18, 2022.

(51) Int. Cl. H01L 21/768; H01L 21/02; H01L 21/311; H01L 23/532; H01L 29/66

(52) U.S. Cl. CPC H01L 21/76835; H01L 21/02112; H01L 21/02126; H01L 21/02203; H01L 21/02274; H01L 21/31144; H01L 21/76832; H01L 23/53295; H01L 29/66795; H01L 21/02205; H01L 21/02211; H01L 21/02214; H01L 21/31116; H01L 21/31122; H01L 21/76802

(57) ABSTRACT

A method for manufacturing a semiconductor device includes forming a source/drain region on a semiconductor fin. The source/drain region is adjacent to a dummy gate. The method further includes forming a first dielectric layer over the source/drain region and the dummy gate. The first dielectric layer has a dielectric constant of 3.5 or less. The first dielectric layer may include boron nitride or silicon dioxide with Si—CH₃ bonds.

### PRIORITY CLAIM AND CROSS REFERENCE

This application is a divisional of U.S. application Ser. No. 17/651,615, filed on Feb. 18, 2022, and entitled “Semiconductor Device and Method of Forming the Same,” which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a FinFET in a three-dimensional view, in accordance with some embodiments.

FIGS. 2, 3, 4, 5, 6, 7, 8A, 8B, 9A, 9B, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, 16D, 17A, 17B, 17C, 17D, 17E, 18A, 18B, 18C, 18D, 19A, 19B, 19C, 19D, 20A, 20B, 20C, 20D, 21A, 21B, 21C, 21D, 22A, 22B, 22C, 22D, 23A, 23B, 23C, 23D, 24A, 24B, 24C, 24D, 25A, 25B, 25C, 25D, 26A, 26B, 26C, 26D, 27A, 27B, 27C, 27D, 28A, 28B, 28C, 28D, 29A, 29B, 29C, 29D, 30A, 30B, 30C, 30D, 31A, 31B, 31C, 31D, 32A, 32B, 32C, 32D, 33A, 33B, 33C, and 33D are cross-sectional and top views of intermediate stages in the manufacturing of FinFETs, in accordance with some embodiments.

FIGS. 34, 35, 36, 37, 38, and 39 are cross-sectional views of intermediate stages in the manufacturing of FinFETs, in accordance with some embodiments.

FIG. 40 is a cross-sectional view of an intermediate stage in the manufacturing of FinFETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, one or more dielectric layers are formed with dielectric constants k in a range of 2.0 to 3.5, which is lower than the dielectric constant of silicon dioxide (k=3.9). This may decrease capacitance of resulting devices comprising the one or more dielectric layers, which is advantageous for increasing device response time. The one or more dielectric layers may be formed with capacitive coupling plasma (CCP) or inductive coupling plasma (ICP) techniques. The one or more dielectric layers may include boron nitride films and/or silicon dioxide comprising Si—CH₃ bonds.

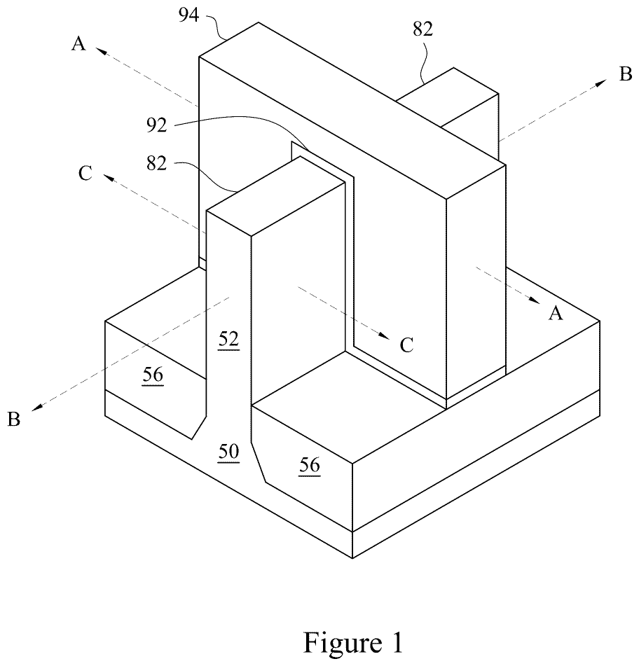

FIG. 1 illustrates an example of a FinFET in a three-dimensional view, in accordance with some embodiments. The FinFET comprises a fin 52 on a substrate 50 (e.g., a semiconductor substrate). Isolation regions 56 are disposed in the substrate 50, and the fin 52 protrudes above and from between neighboring isolation regions 56. Although the isolation regions 56 are described/illustrated as being separate from the substrate 50, as used herein the term “substrate” may be used to refer to just the semiconductor substrate or a semiconductor substrate inclusive of isolation regions. Additionally, although the fin 52 is illustrated as a single, continuous material as the substrate 50, the fin 52 and/or the substrate 50 may comprise a single material or a plurality of materials. In this context, the fin 52 refers to the portion extending between the neighboring isolation regions 56.

A gate dielectric layer 92 is along sidewalls and over a top surface of the fin 52, and a gate electrode 94 is over the gate dielectric layer 92. Source/drain regions 82 are disposed in opposite sides of the fin 52 with respect to the gate dielectric layer 92 and gate electrode 94. FIG. 1 further illustrates reference cross-sections that are used in later figures. Cross-section A-A is along a longitudinal axis of the gate electrode 94 and in a direction, for example, perpendicular to the direction of current flow between the source/drain regions 82 of the FinFET. Cross-section B-B is perpendicular to cross-section A-A and is along a longitudinal axis of the fin 52 and in a direction of, for example, a current flow between the source/drain regions 82 of the FinFET. Cross-section C-C is parallel to cross-section A-A and extends through a source/drain region of the FinFET. Subsequent figures refer to these reference cross-sections for clarity.

Some embodiments discussed herein are discussed in the context of FinFETs formed using a gate-last process. In other embodiments, a gate-first process may be used. Also, some embodiments contemplate aspects used in planar devices, such as planar FETs, nanostructure (e.g., nanosheet, nanowire, gate-all-around, or the like) field effect transistors (NSFETs), or the like.

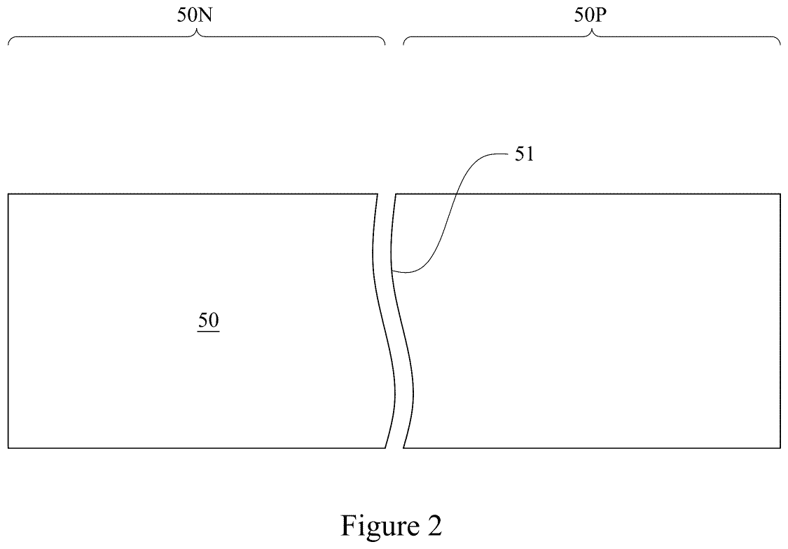

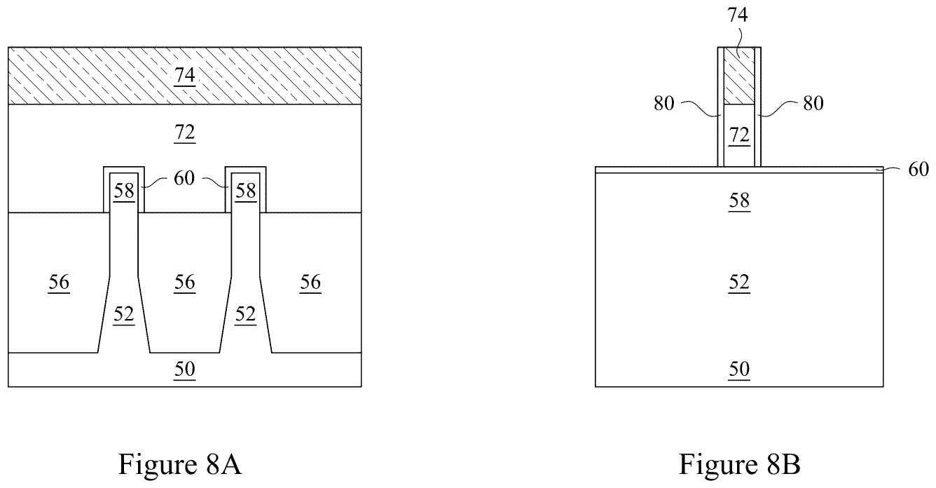

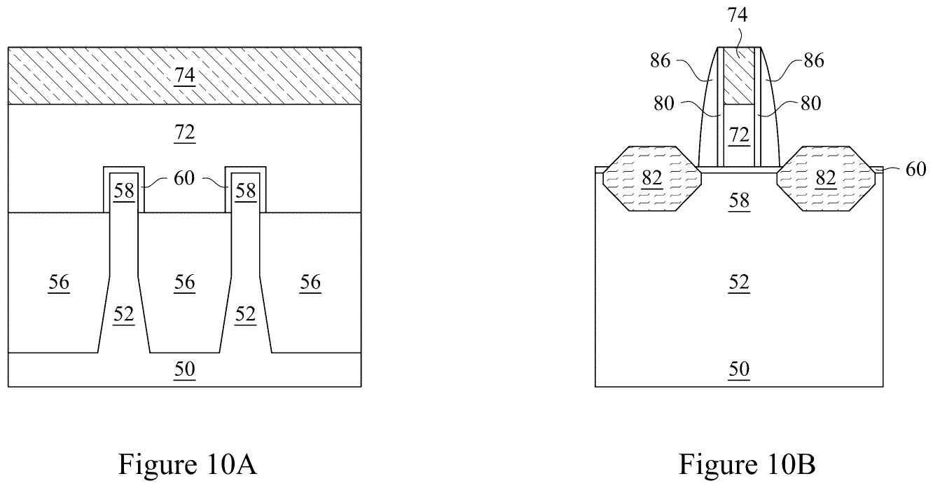

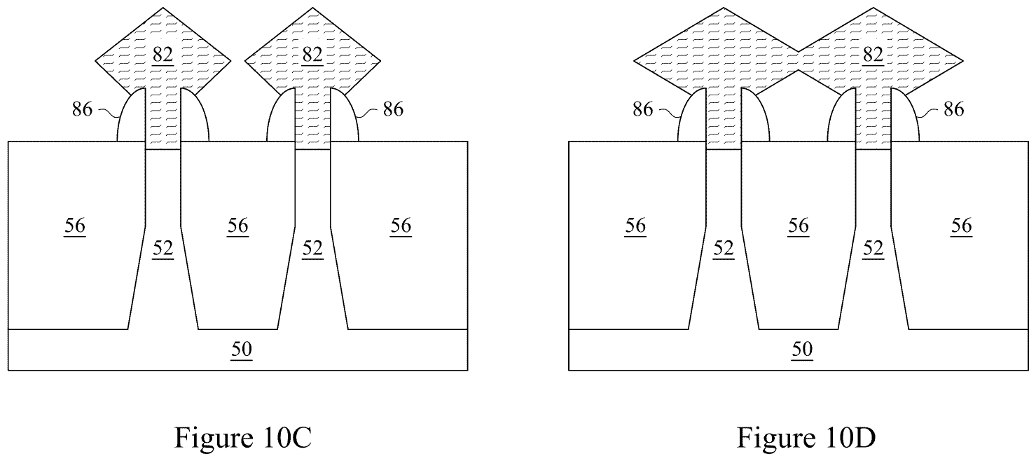

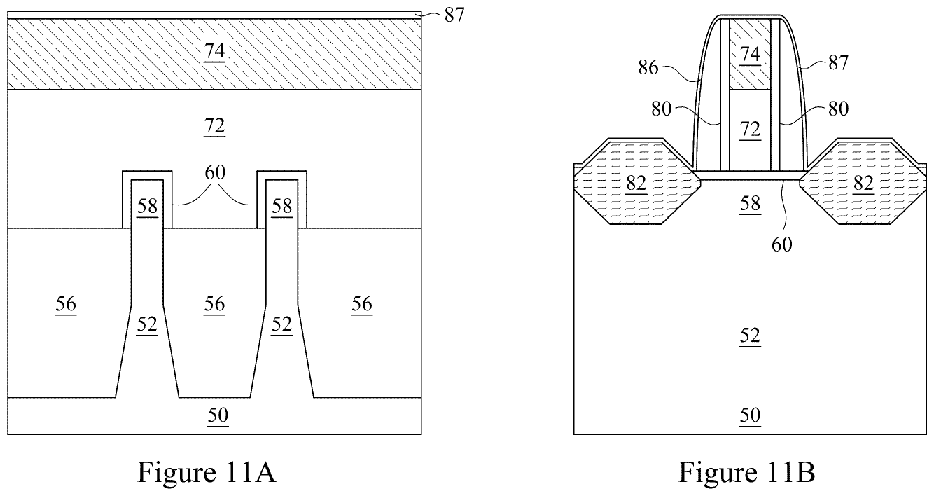

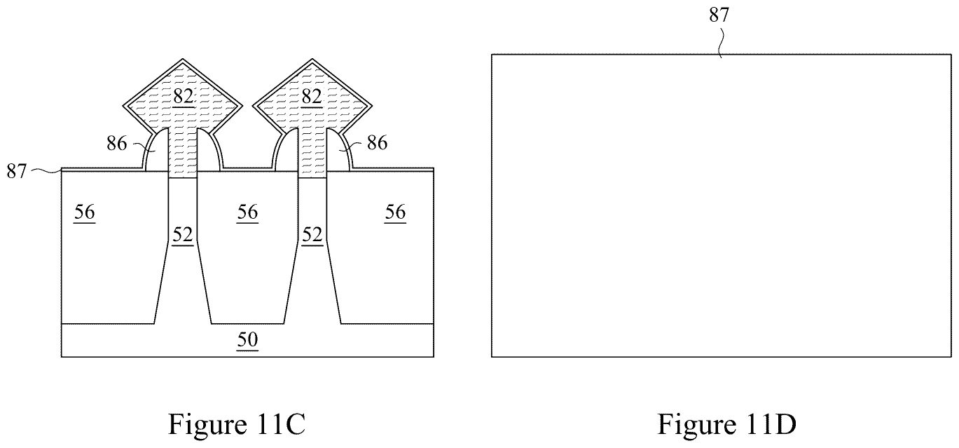

FIGS. 2 through 33D are cross-sectional and top views of intermediate stages in the manufacturing of FinFETs, in accordance with some embodiments. FIGS. 2 through 7 illustrate reference cross-section A-A illustrated in FIG. 1, except for multiple fins/FinFETs. FIGS. 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, and 33A are illustrated along reference cross-section A-A illustrated in FIG. 1, and FIGS. 8B, 9B, 10B, 11B, 12B, 13B, 14B, 14C, 15B, 16B, 17B, 17E, 18B, 19B, 20B, 21B, 22B, 23B, 24B, 25B, 26B, 27B, 28B, 29B, 30B, 31B, 32B, and 33B are illustrated along a similar cross-section B-B illustrated in FIG. 1, except for multiple fins/FinFETs. FIGS. 10C, 10D, 11C, 12C, 13C, 14C, 15C, 16C, 17C, 18C, 19C, 20C, 21C, 22C, 23C, 24C, 25C, 26C, 27C, 28C, 29C, 30C, 31C, 32C, and 33C are illustrated along reference cross-section C-C illustrated in FIG. 1, except for multiple fins/FinFETs. FIGS. 11D, 12D, 13D, 14D, 15D, 16D, 17D, 18D, 19D, 20D, 21D, 22D, 23D, 24D, 25D, 26D, 27D, 28D, 29D, 30D, 31D, 32D, and 33D illustrate top views of respective intermediate stages in the manufacturing of FinFETs, in accordance with some embodiments.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type FinFETs. The p-type region 50P can be for forming p-type devices, such as PMOS transistors, e.g., p-type FinFETs. The n-type region 50N may be physically separated from the p-type region 50P (as illustrated by divider 51), and any number of device features (e.g., other active devices, doped regions, isolation structures, etc.) may be disposed between the n-type region 50N and the p-type region 50P.

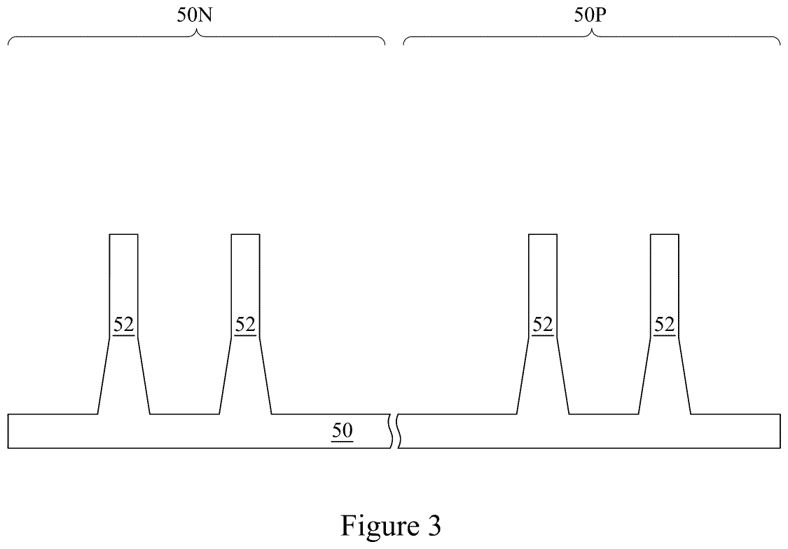

In FIG. 3, fins 52 are formed in the substrate 50. The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), the like, or a combination thereof. The etch may be anisotropic.

The fins may be patterned by any suitable method. For example, the fins 52 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. In some embodiments, the mask (or other layer) may remain on the fins 52.

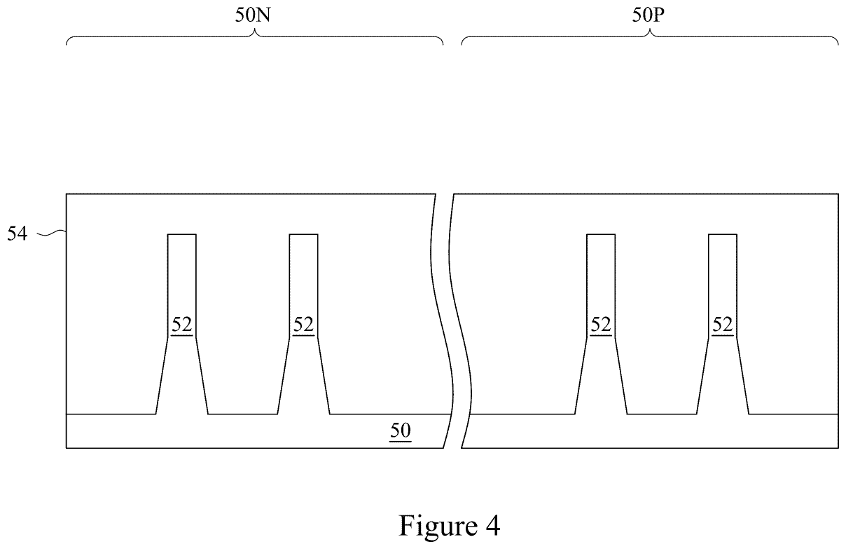

In FIG. 4, an insulation material 54 is formed over the substrate 50 and between neighboring fins 52. The insulation material 54 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52. Although the insulation material 54 is illustrated as a single layer, some embodiments may utilize multiple layers. For example, in some embodiments a liner (not shown) may first be formed along a surface of the substrate 50 and the fins 52. Thereafter, a fill material, such as those discussed above may be formed over the liner.

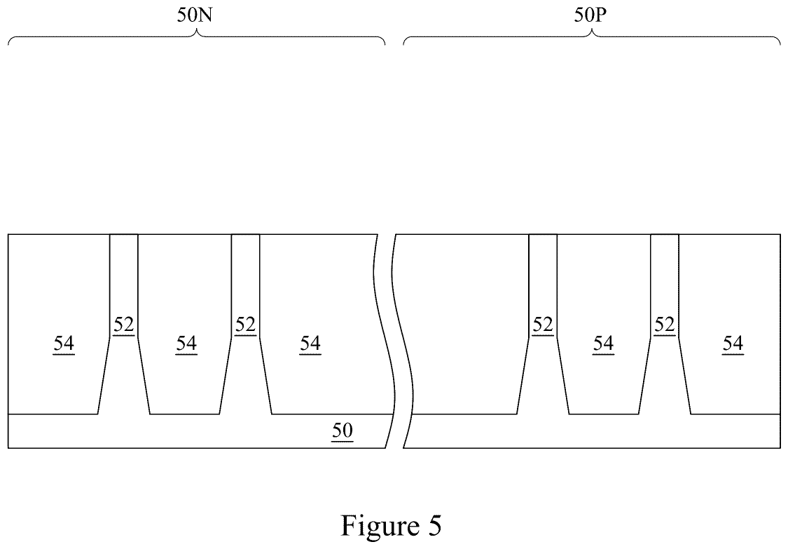

In FIG. 5, a removal process is applied to the insulation material 54 to remove excess insulation material 54 over the fins 52. In some embodiments, a planarization process such as a chemical mechanical polish (CMP), an etch-back process, combinations thereof, or the like may be utilized. The planarization process exposes the fins 52 such that top surfaces of the fins 52 and the insulation material 54 are level after the planarization process is complete. In embodiments in which a mask remains on the fins 52, the planarization process may expose the mask or remove the mask such that top surfaces of the mask or the fins 52, respectively, and the insulation material 54 are level after the planarization process is complete.

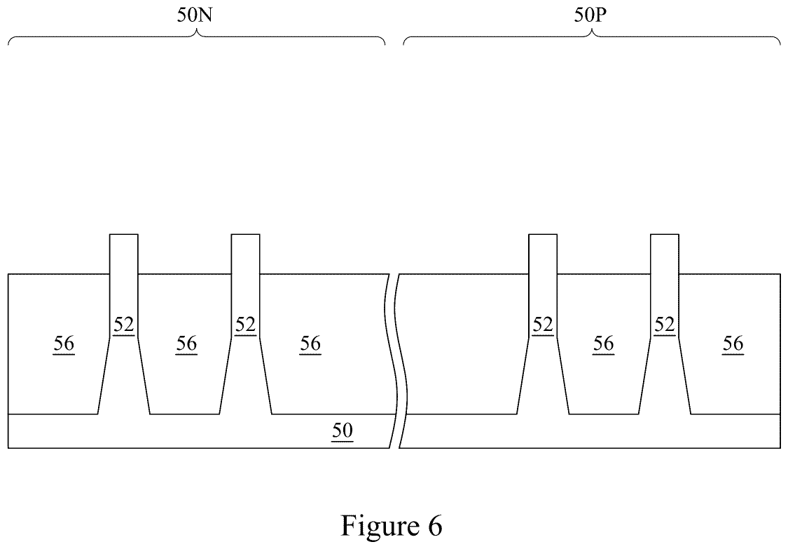

In FIG. 6, the insulation material 54 is recessed to form Shallow Trench Isolation (STI) regions 56. The insulation material 54 is recessed such that upper portions of fins 52 in the n-type region 50N and in the p-type region 50P protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the material of the insulation material 54 (e.g., etches the material of the insulation material 54 at a faster rate than the material of the fins 52). For example, an oxide removal using dilute hydrofluoric (dHF) acid or a chemical oxide removal using HF/NF₃ or NH₃/NF₃ may be used.

The process described with respect to FIGS. 2 through 6 is just one example of how the fins 52 may be formed. In some embodiments, the fins may be formed by an epitaxial growth process. For example, a dielectric layer can be formed over a top surface of the substrate 50, and trenches can be etched through the dielectric layer to expose the underlying substrate 50. Homoepitaxial structures can be epitaxially grown in the trenches, and the dielectric layer can be recessed such that the homoepitaxial structures protrude from the dielectric layer to form fins. Additionally, in some embodiments, heteroepitaxial structures can be used for the fins 52. For example, the fins 52 in FIG. 5 can be recessed, and a material different from the fins 52 may be epitaxially grown over the recessed fins 52. In such embodiments, the fins 52 comprise the recessed material as well as the epitaxially grown material disposed over the recessed material. In an even further embodiment, a dielectric layer can be formed over a top surface of the substrate 50, and trenches can be etched through the dielectric layer. Heteroepitaxial structures can then be epitaxially grown in the trenches using a material different from the substrate 50, and the dielectric layer can be recessed such that the heteroepitaxial structures protrude from the dielectric layer to form the fins 52. In some embodiments where homoepitaxial or heteroepitaxial structures are epitaxially grown, the epitaxially grown materials may be in situ doped during growth, which may obviate prior and subsequent implantations although in situ and implantation doping may be used together.

Still further, it may be advantageous to epitaxially grow a material in n-type region 50N (e.g., an NMOS region) different from the material in p-type region 50P (e.g., a PMOS region). In various embodiments, upper portions of the fins 52 may be formed from silicon-germanium (SiₓGen₁₋ₓ, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

Further in FIG. 6, appropriate wells (not shown) may be formed in the fins 52 and/or the substrate 50. In some embodiments, a P well may be formed in the n-type region 50N, and an N well may be formed in the p-type region 50P. In some embodiments, a P well or an N well are formed in both the n-type region 50N and the p-type region 50P.

In the embodiments with different well types, the different implant steps for the n-type region 50N and the p-type region 50P may be achieved using a photoresist and/or other masks (not shown). For example, a photoresist may be formed over the fins 52 and the STI regions 56 in the n-type region 50N. The photoresist is patterned to expose the p-type region 50P of the substrate 50. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration of equal to or less than 10¹⁸ cm⁻³, such as between about 10¹⁶ cm⁻³ and about 10¹⁸ cm⁻³. After the implant, the photoresist is removed, such as by an acceptable ashing process.

Following the implanting of the p-type region 50P, a photoresist is formed over the fins 52 and the STI regions 56 in the p-type region 50P. The photoresist is patterned to expose the n-type region 50N of the substrate 50. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration of equal to or less than 10¹⁸ cm⁻³, such as between about 10¹⁶ cm⁻³ and about 10¹⁸ cm⁻³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

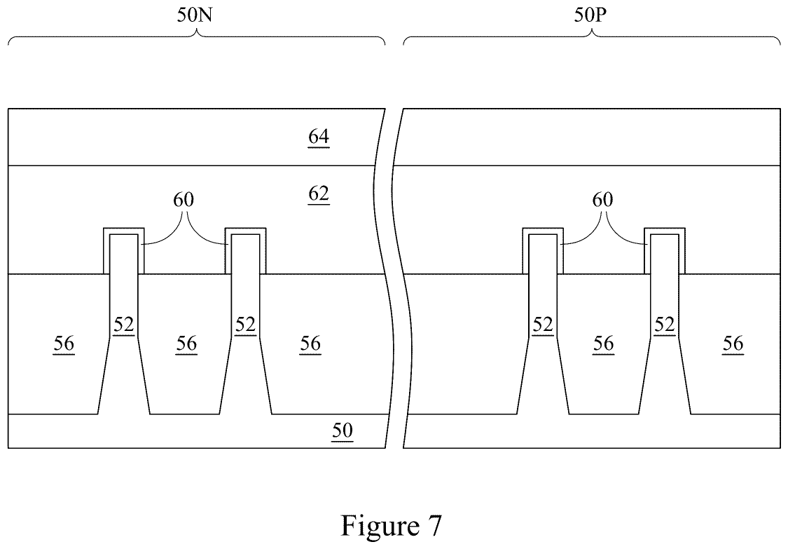

In FIG. 7, a dummy dielectric layer 60 is formed on the fins 52. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized, such as by a CMP. The mask layer 64 may be deposited over the dummy gate layer 62. The dummy gate layer 62 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques for depositing the selected material. The dummy gate layer 62 may be made of other materials that have a high etching selectivity from the etching of isolation regions, e.g., the STI regions 56 and/or the dummy dielectric layer 60. The mask layer 64 may include one or more layers of, for example, silicon nitride, silicon oxynitride, or the like. In this example, a single dummy gate layer 62 and a single mask layer 64 are formed across the n-type region 50N and the p-type region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56, extending over the STI regions and between the dummy gate layer 62 and the STI regions 56.

FIGS. 8A through 16B illustrate various additional steps in the manufacturing of embodiment devices. FIGS. 8A through 16B illustrate features in either of the n-type region 50N and the p-type region 50P. For example, the structures illustrated in FIGS. 8A through 16B may be applicable to both the n-type region 50N and the p-type region 50P. Differences (if any) in the structures of the n-type region 50N and the p-type region 50P are described in the text accompanying each figure.

In FIGS. 8A and 8B, the mask layer 64 (see FIG. 7) may be patterned using acceptable photolithography and etching techniques to form masks 74. The pattern of the masks 74 then may be transferred to the dummy gate layer 62. In some embodiments (not illustrated), the pattern of the masks 74 may also be transferred to the dummy dielectric layer 60 by an acceptable etching technique to form dummy gates 72. The dummy gates 72 cover respective channel regions 58 of the fins 52. The pattern of the masks 74 may be used to physically separate each of the dummy gates 72 from adjacent dummy gates. The dummy gates 72 may also have a lengthwise direction substantially perpendicular to the lengthwise direction of respective epitaxial fins 52.

Further in FIGS. 8A and 8B, gate seal spacers 80 can be formed on exposed surfaces of the dummy gates 72, the masks 74, and/or the fins 52. A thermal oxidation or a deposition followed by an anisotropic etch may form the gate seal spacers 80. The gate seal spacers 80 may be formed of silicon oxide, silicon nitride, silicon oxynitride, or the like.

After the formation of the gate seal spacers 80, implants for lightly doped source/drain (LDD) regions (not explicitly illustrated) may be performed. In the embodiments with different device types, similar to the implants discussed above in FIG. 6, a mask, such as a photoresist, may be formed over the n-type region 50N, while exposing the p-type region 50P, and appropriate type (e.g., p-type) impurities may be implanted into the exposed fins 52 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 52 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities of from about 10¹⁵ cm⁻³ to about 10¹⁹ cm⁻³. An anneal may be used to repair implant damage and to activate the implanted impurities.

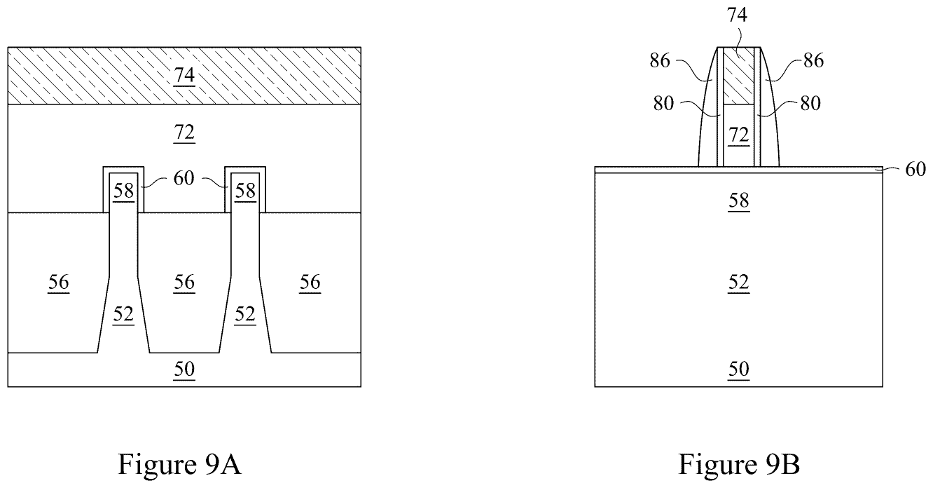

In FIGS. 9A and 9B, gate spacers 86 are formed on the gate seal spacers 80 along sidewalls of the dummy gates 72 and the masks 74. The gate spacers 86 may be formed by conformally depositing an insulating material and subsequently anisotropically etching the insulating material. The insulating material of the gate spacers 86 may be silicon oxide, silicon nitride, silicon oxynitride, silicon carbonitride, a combination thereof, or the like.

It is noted that the above disclosure generally describes a process of forming spacers and LDD regions. Other processes and sequences may be used. For example, fewer or additional spacers may be utilized, different sequence of steps may be utilized (e.g., the gate seal spacers 80 may not be etched prior to forming the gate spacers 86, yielding “L-shaped” gate seal spacers, spacers may be formed and removed, and/or the like. Furthermore, the n-type and p-type devices may be formed using different structures and steps. For example, LDD regions for n-type devices and for p-type devices may be formed after forming the gate seal spacers 80.

In FIGS. 10A and 10B epitaxial source/drain regions 82 are formed in the fins 52. The epitaxial source/drain regions 82 are formed in the fins 52 such that each dummy gate 72 is disposed between respective neighboring pairs of the epitaxial source/drain regions 82. In some embodiments the epitaxial source/drain regions 82 may extend into, and may also penetrate through, the fins 52. In some embodiments, the gate spacers 86 are used to separate the epitaxial source/drain regions 82 from the dummy gates 72 by an appropriate lateral distance so that the epitaxial source/drain regions 82 do not short out subsequently formed gates of the resulting FinFETs. A material of the epitaxial source/drain regions 82 may be selected to exert stress in the respective channel regions 58, thereby improving performance.

The epitaxial source/drain regions 82 in the n-type region 50N may be formed by masking the p-type region 50P and etching source/drain regions of the fins 52 in the n-type region 50N to form recesses in the fins 52. Then, the epitaxial source/drain regions 82 in the n-type region 50N are epitaxially grown in the recesses. The epitaxial source/drain regions 82 may include any acceptable material, such as appropriate for n-type FinFETs. For example, if the fin 52 is silicon, the epitaxial source/drain regions 82 in the n-type region 50N may include materials exerting a tensile strain in the channel region 58, such as silicon, silicon carbide, phosphorous doped silicon carbide, silicon phosphide, or the like. The epitaxial source/drain regions 82 in the n-type region 50N may have surfaces raised from respective surfaces of the fins 52 and may have facets.

The epitaxial source/drain regions 82 in the p-type region 50P may be formed by masking the n-type region 50N and etching source/drain regions of the fins 52 in the p-type region 50P to form recesses in the fins 52. Then, the epitaxial source/drain regions 82 in the p-type region 50P are epitaxially grown in the recesses. The epitaxial source/drain regions 82 may include any acceptable material, such as appropriate for p-type FinFETs. For example, if the fin 52 is silicon, the epitaxial source/drain regions 82 in the p-type region 50P may comprise materials exerting a compressive strain in the channel region 58, such as silicon-germanium, boron doped silicon-germanium, germanium, germanium tin, or the like. The epitaxial source/drain regions 82 in the p-type region 50P may have surfaces raised from respective surfaces of the fins 52 and may have facets.

The epitaxial source/drain regions 82 and/or the fins 52 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 82 may be in situ doped during growth.

As a result of the epitaxy processes used to form the epitaxial source/drain regions 82 in the n-type region 50N and the p-type region 50P, upper surfaces of the epitaxial source/drain regions have facets which expand laterally outward beyond sidewalls of the fins 52. In some embodiments, adjacent source/drain regions 82 remain separated after the epitaxy process is completed as illustrated by FIG. 10C. In some embodiments, these facets cause adjacent source/drain regions 82 of a same FinFET to merge as illustrated by FIG. 10D. In the embodiments illustrated in FIGS. 10C and 10D, gate spacers 86 are formed covering a portion of the sidewalls of the fins 52 that extend above the STI regions 56 thereby blocking the epitaxial growth. In some other embodiments, the spacer etch used to form the gate spacers 86 may be adjusted to remove the spacer material to allow the epitaxially grown region to extend to the surface of the STI region 56.

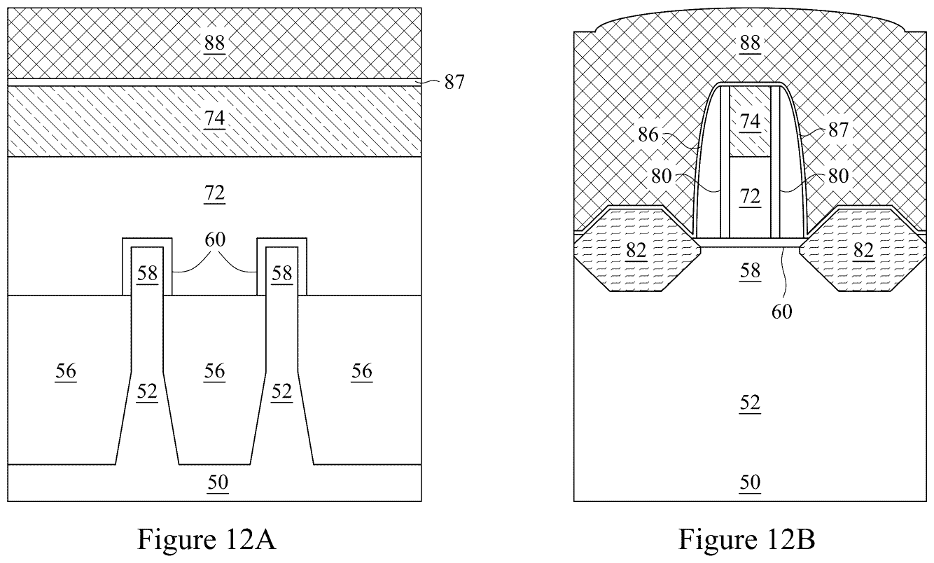

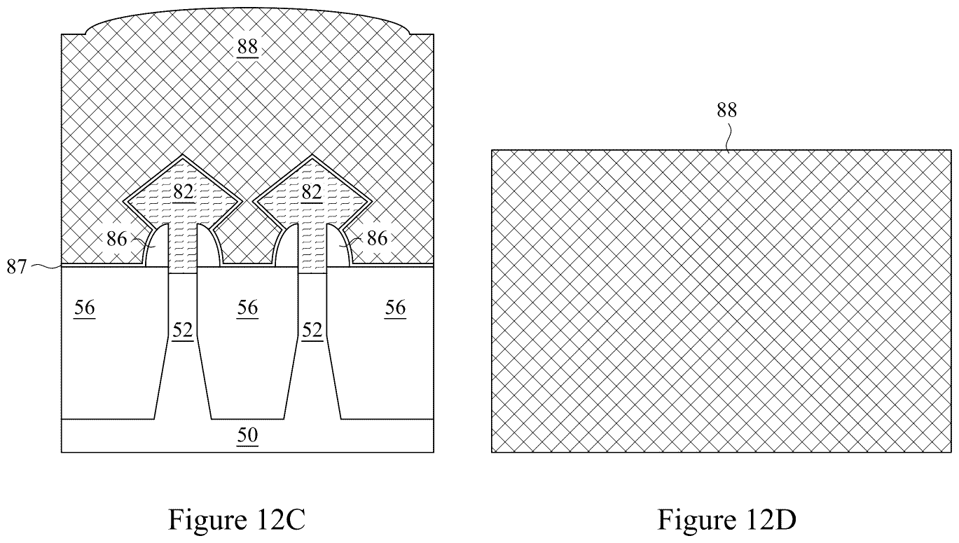

In FIGS. 11A-11D, a contact etch stop layer (CESL) 87 is formed over the structure illustrated in FIGS. 10A-10C, including the epitaxial source/drain regions 82, the masks 74, and the gate spacers 86, wherein FIG. 11D (and subsequent “D” figures such as 12D, 13D, etc.) illustrates a top down view of the structure. The CESL 87 may comprise a dielectric material, such as silicon nitride, silicon oxide, silicon oxynitride, silicon carbide, silicon oxycarbide, silicon oxycarbonitride, or the like, having a lower etch rate than the material of the subsequently formed first interlayer dielectric (ILD) 88 (see below, FIGS. 12A-12D).

In FIGS. 12A-12D, a first interlayer dielectric (ILD) 88 is deposited over the structure illustrated in FIGS. 11A-11D. The first ILD 88 insulates electrically conductive and semiconductive features (e.g., the source/drain regions 82 and subsequently formed gate electrodes and conductive contacts) from each other. The first ILD 88 is formed of a dielectric material, and may be deposited by any suitable method, such as plasma-enhanced CVD (PECVD), CVD, or FCVD.

In some embodiments, the first ILD 88 is a low-k dielectric material with a dielectric constant k in a range of 2.0 to 3.5, which is lower than the dielectric constant of silicon dioxide (k=3.9). The first ILD 88 having a dielectric constant k in a range of 2.0 to 3.5 may decrease capacitance of a resulting device, which is advantageous for increasing device response time. The first ILD 88 having a dielectric constant k less than 2.0 may be disadvantageous because it may lead to the film having poor quality and low hardness, decreasing reliability of the first ILD 88.

The first ILD 88 may be formed with a plasma process using capacitive coupling plasma (CCP), inductive coupling plasma (ICP), the like, or a combination thereof. In some embodiments, the plasma process is performed using an RF frequency in a range of 400 KHz to 27 MHz, with a typical RF frequency being, e.g., 13.56 MHz. In some embodiments, the plasma process is performed at a pressure in a range of 1 torr to 10 torr in a CCP tool or at a pressure in a range of 3 mtorr to 500 mtorr in an ICP tool. In some embodiments, the plasma process is performed at a temperature in a range of 25° C. to 400° C.

In some embodiments, the first ILD 88 is a film comprising boron nitride (BN), and may be formed using, e.g., the CCP or ICP technique. The boron nitride film may have a dielectric constant k in a range of 2.7 to 3.5, which is lower than the dielectric constant of silicon dioxide (k=3.9). In some embodiments, the boron nitride film is formed using the plasma processes described above and with using a precursor such as borazine (B₃N₃H₆) as a process gas. The borazine may be introduced into the processing chamber at a flow rate in a range of 10 sccm to 1000 sccm. However, any suitable flow rates may be utilized.

In other embodiments, the boron nitride film is formed using boron trichloride (BCl₃) and nitrogen (N₂) as process gases. In this embodiment, the boron trichloride may be introduced into the processing chamber at a flow rate in a range of 10 sccm to 1000 sccm, and the nitrogen may be introduced into the processing chamber at a flow rate in a range of 10 sccm to 1000 sccm. However, any suitable flow rates, and any suitable precursors, may be utilized.

In still other embodiments, the first ILD 88 is a low-k dielectric comprising silicon dioxide with Si—CH₃ bonds formed within the first ILD 88, and may be formed using a CCP or ICP technique wherein the precursor gases do not include O₂ gas. The Si—CH₃ bonds may increase porosity and lower the dielectric constant. In some embodiments, a ratio of a density of Si—CH₃ bonds to a density of Si—O bonds in the first ILD 88 is in a range of 50% to 120%. A first precursor gas which contains oxygen, such as MDEOS (also referred to as DEMS diethoxymethylsilane SiH(CH₃)(OC₂H₅)₂) or TEOS (tetraethylorthosilicate Si(OC₂H₅)₄), may be used to provide the O atoms incorporated in the low-k dielectric to form Si—O bonds. The first precursor may be introduced into the processing chamber at a flow rate in a range of 10 sccm to 1000 sccm. A second precursor gas (e.g., ATRP (alpha-Terpinene C₁₀H₁₆), propane C₃H₈, BCHD (bicycloheptadiene C₇H₈), or C₆H₁₀(C₂H₅)₂) containing a hydrocarbon (CₓH_{y}, where x may be from about 3 to about 10, and y may be from about 8 to about 30) may be used in combination with the first precursor gas. The second precursor gas may react with the first precursor gas to form Si—CH₃ bonds within the deposited silicon dioxide. The second precursor may be introduced into the processing chamber at a flow rate at a flow rate in a range of 10 sccm to 1000 sccm.

In other embodiments, the first ILD 88 is a dielectric material with a dielectric constant greater than 3.5, such as a dielectric constant of 3.9 or greater. The first ILD 88 may include phospho-silicate glass (PSG), boro-silicate glass (BSG), boron-doped phospho-silicate glass (BPSG), undoped silicate glass (USG), or the like. Other insulation materials formed by any acceptable process may be used.

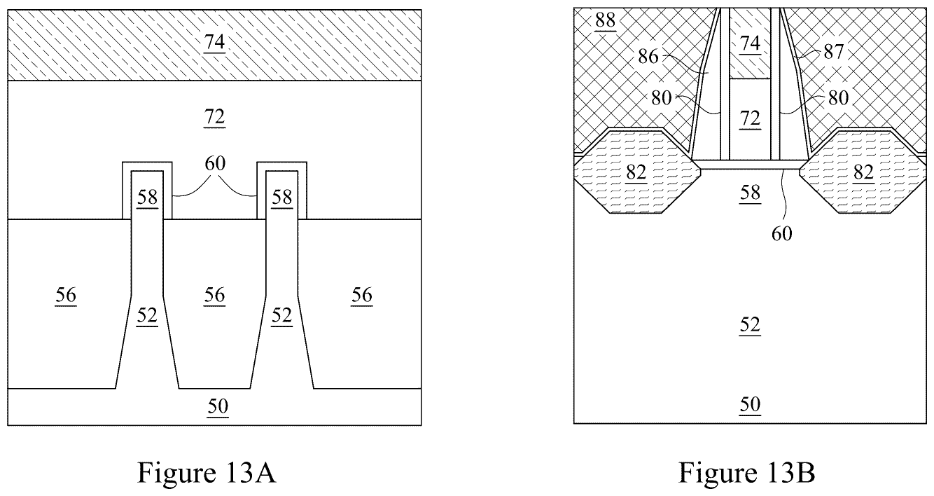

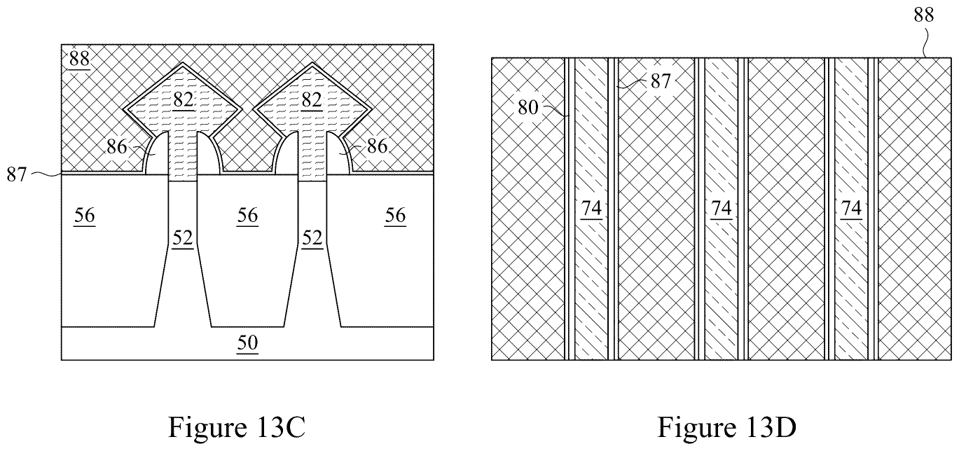

In FIGS. 13A-13D, a planarization process, such as a CMP, may be performed to level the top surface of the first ILD 88 with the top surfaces of the masks 74. After the planarization process, top surfaces of the masks 74, the gate seal spacers 80, the gate spacers 86, and the first ILD 88 are level. Accordingly, the top surfaces of the masks 74 are exposed through the first ILD 88. In some embodiments, the masks 74 are removed by the planarization, in which case the planarization process levels the top surface of the first ILD 88 with the top surfaces of the dummy gates 72.

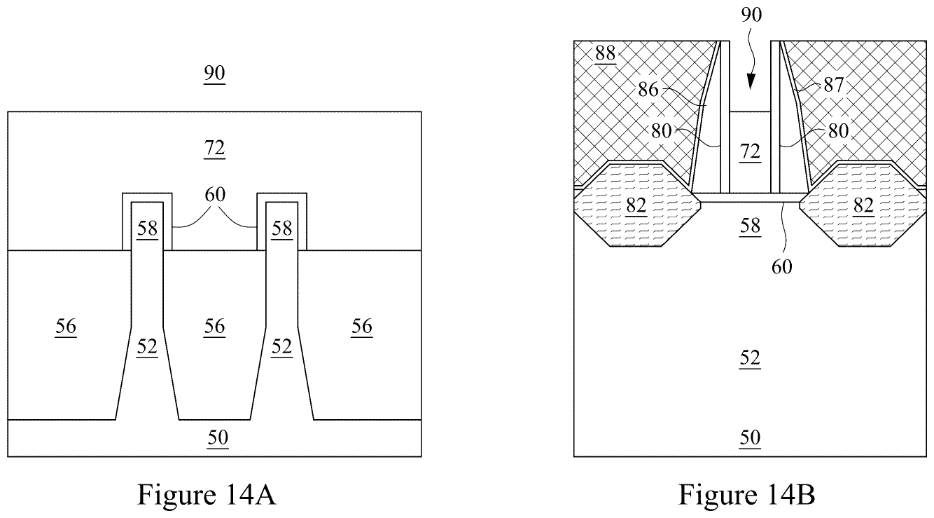

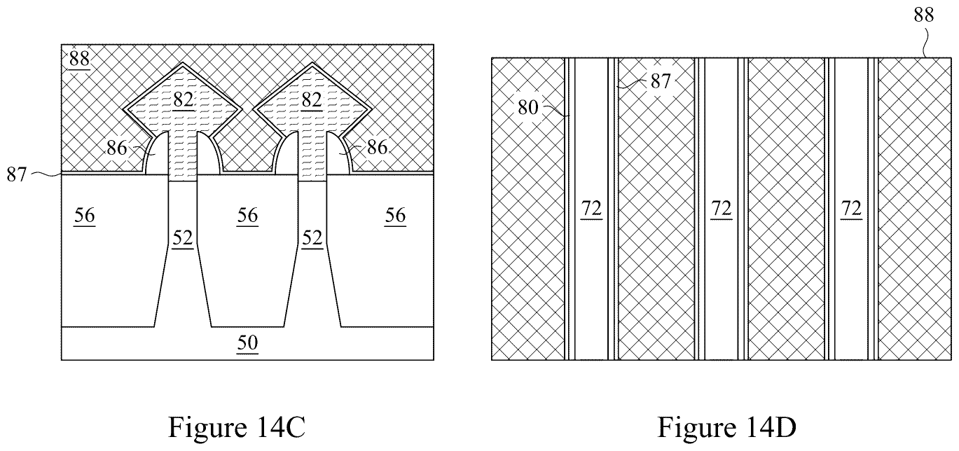

In FIGS. 14A-14D, the masks 74 are removed in an etching step(s), so that recesses 90 are formed. In some embodiments, the masks 74 are removed by an anisotropic dry etch process. For example, the etching process may include a dry etch process using reaction gas(es) that selectively etch the masks 74 with little or no etching of the first ILD 88 or the gate seal spacers 80. Removing the masks 74 exposes a top surface of the dummy gates 72. In some embodiments, the masks 74 are removed by a planarization that also removes top portions of the first ILD 88, the CESL 87, the gate seal spacers 80, and the gate spacers 86.

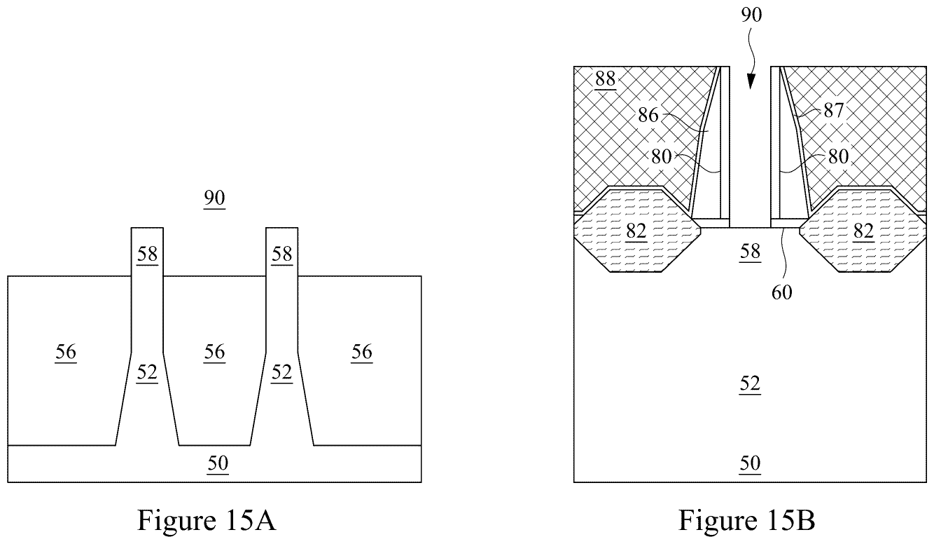

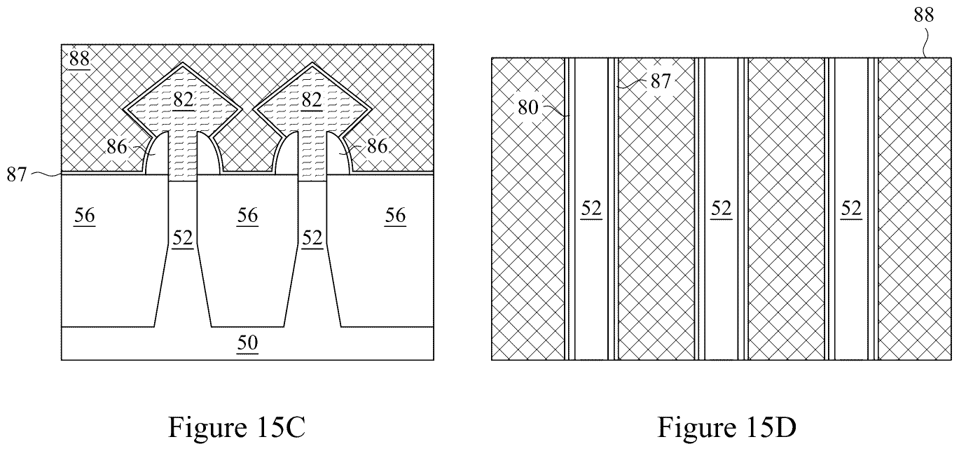

In FIGS. 15A-15D, the dummy gates 72 are removed in an etching step(s), so that recesses 90 are extended. Portions of the dummy dielectric layer 60 in the recesses 90 may also be removed. In some embodiments, only the dummy gates 72 are removed and the dummy dielectric layer 60 remains and is exposed by the recesses 90. In some embodiments, the dummy dielectric layer 60 is removed from recesses 90 in a first region of a die (e.g., a core logic region) and remains in recesses 90 in a second region of the die (e.g., an input/output region). In some embodiments, the dummy gates 72 are removed by an anisotropic dry etch process or a dry etch followed by a wet etch process. For example, the etching process may include a dry etch process using reaction gas(es) that selectively etch the dummy gates 72 with little or no etching of the first ILD 88 or the gate seal spacers 80. Each recess 90 exposes and/or overlies a channel region 58 of a respective fin 52. Each channel region 58 is disposed between neighboring pairs of the epitaxial source/drain regions 82. During the removal, the dummy dielectric layer 60 may be used as an etch stop layer when the dummy gates 72 are etched. The dummy dielectric layer 60 may then be optionally removed after the removal of the dummy gates 72.

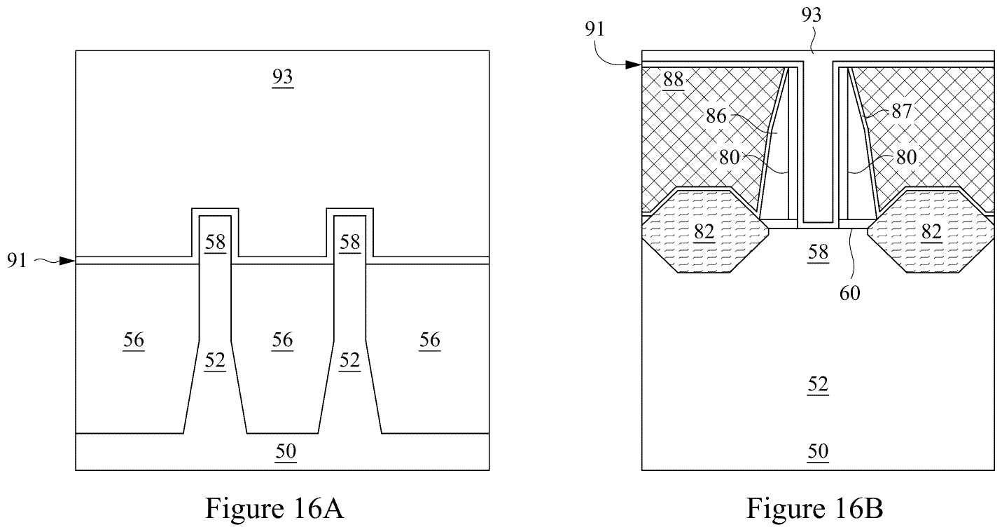

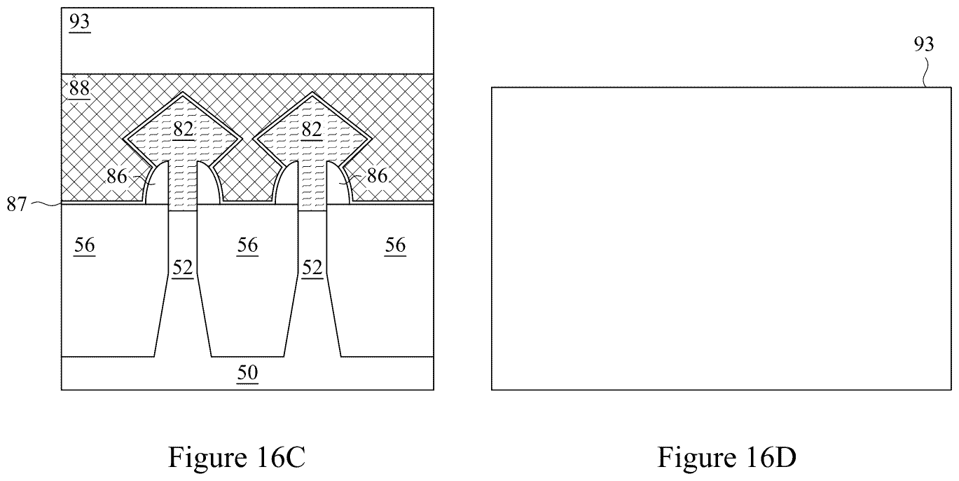

In FIGS. 16A-16D, gate dielectric layer(s) 91 and gate electrode layer(s) 934 are formed for replacement gates. The gate dielectric layer(s) 91 comprise one or more layers deposited in the recesses 90, such as on the top surfaces and the sidewalls of the fins 52 and on sidewalls of the gate seal spacers 80/gate spacers 86. The gate dielectric layer(s) 91 may also be formed on the top surface of the first ILD 88. In some embodiments, the gate dielectric layer(s) 91 comprise one or more dielectric layers, such as one or more layers of silicon oxide, silicon nitride, metal oxide, metal silicate, or the like. For example, in some embodiments, the gate dielectric layer(s) 91 include an interfacial layer of silicon oxide formed by thermal or chemical oxidation and an overlying high-k dielectric material, such as a metal oxide or a silicate of hafnium, aluminum, zirconium, lanthanum, manganese, barium, titanium, lead, and combinations thereof. The gate dielectric layer(s) 91 may include a dielectric layer having a k value greater than about 7.0. The formation methods of the gate dielectric layer(s) 91 may include Molecular-Beam Deposition (MBD), ALD, PECVD, and the like. In embodiments where portions of the dummy dielectric layer 60 remains in the recesses 90, the gate dielectric layer(s) 91 include a material of the dummy dielectric layer 60 (e.g., SiO₂).

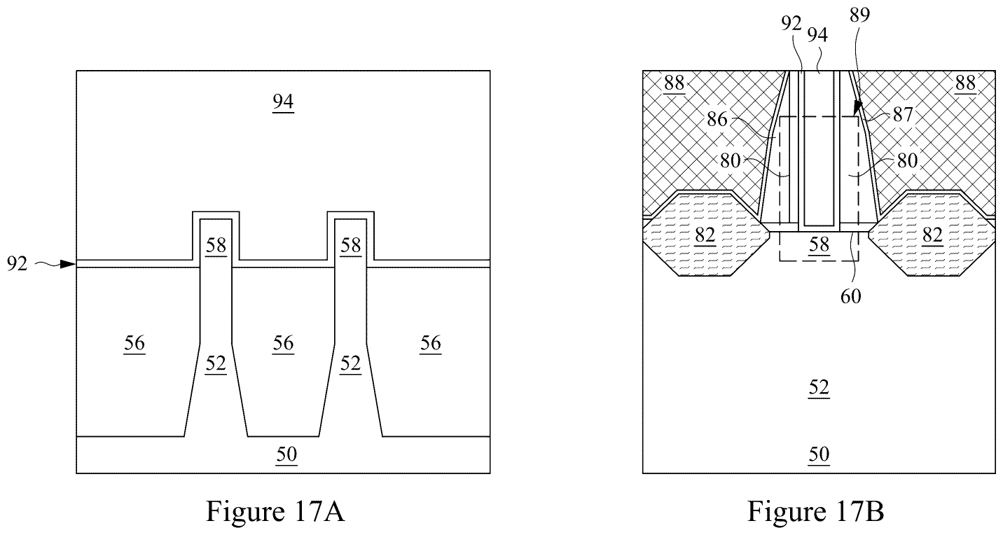

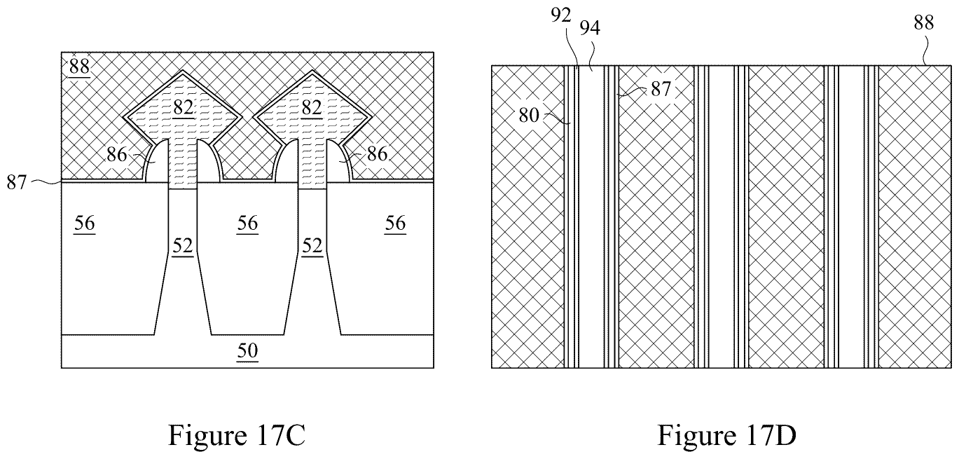

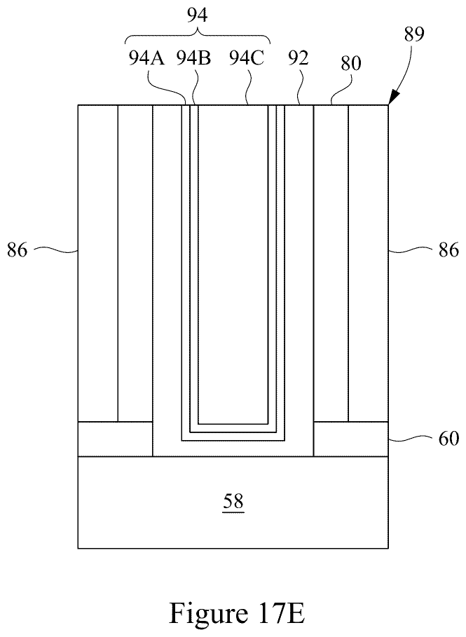

The gate electrode layer(s) 93 are deposited over the gate dielectric layer(s) 91, respectively, and fill the remaining portions of the recesses 90. The gate electrode layer(s) 93 may include a metal-containing material such as titanium nitride, titanium oxide, tantalum nitride, tantalum carbide, cobalt, ruthenium, aluminum, tungsten, combinations thereof, or multi-layers thereof. For example, although a single layer gate electrode layer 93 is illustrated in FIGS. 16A-16C, the gate electrode layer(s) 93 may comprise any number of liner layers, any number of work function tuning layers, and a fill material (see below, FIG. 17E).

The formation of the gate dielectric layer(s) 91 in the n-type region 50N and the p-type region 50P may occur simultaneously such that the gate dielectric layer(s) 91 in each region are formed from the same materials, and the formation of the gate electrode layer(s) 93 may occur simultaneously such that the gate dielectric layer(s) 91 and the gate electrode layer(s) 93 in each region are formed from the same materials. In some embodiments, the gate dielectric layers 92 in each region may be formed by distinct processes, such that the gate dielectric layer(s) 91 may be different materials, and/or the gate electrode layer(s) 93 in each region may be formed by distinct processes, such that the gate dielectric layer(s) 91 and the gate electrode layer(s) 93 may be different materials. Various masking steps may be used to mask and expose appropriate regions when using distinct processes.

In FIGS. 17A-17D, the gate dielectric layers 91 and the gate electrode layer(s) 94 are planarized to form gate dielectrics 92 and gate electrodes 94. FIG. 17E illustrates a detailed view of region 89 of FIG. 17B. After the filling of the recesses 90, a planarization process, such as a CMP, may be performed to remove the excess portions of the gate dielectric layer(s) 91 and the material of the gate electrode layer(s) 93, which excess portions are over the top surface of the ILD 88. The remaining portions of material of the gate electrode layer(s) 93 and the gate dielectric layer(s) 91 thus form gate electrodes 94 and gate dielectrics 91 of replacement gates of the resulting FinFETs. The gate electrodes 94 and the gate dielectric layers 92 may be collectively referred to as a “gate structure.” The gate and the gate structures may extend along sidewalls of a channel region 58 of the fins 52. Although a single layer gate electrode 94 is illustrated in FIGS. 17A-17D, the gate electrode 94 may comprise any number of liner layers, any number of work function tuning layers, and a fill material as illustrated in FIG. 17E.

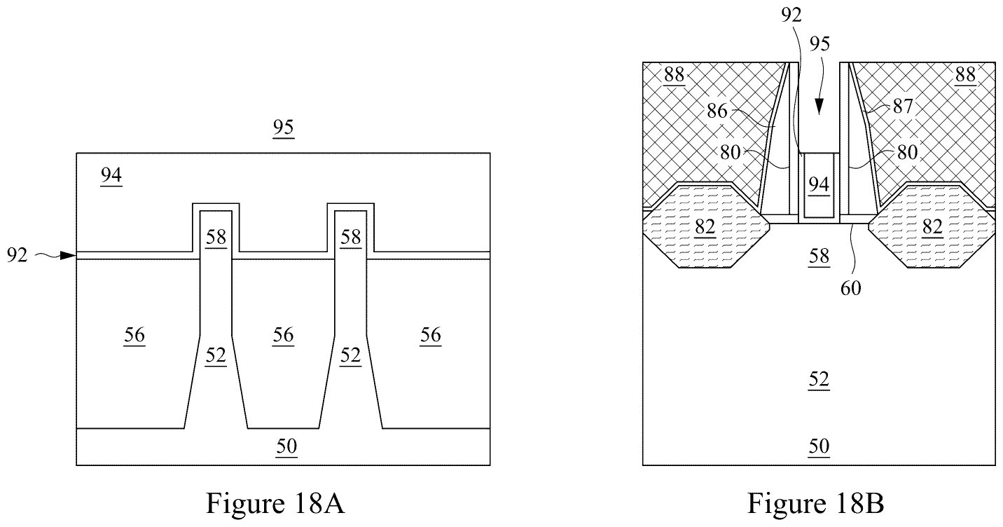

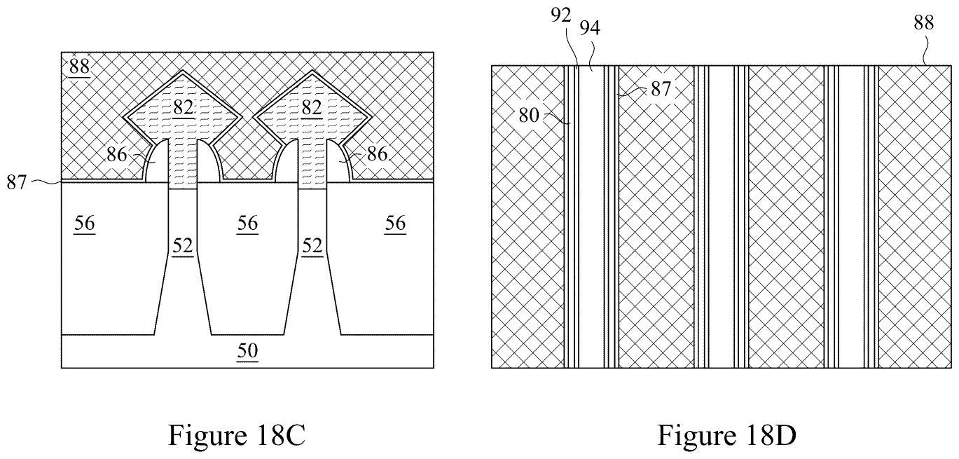

In FIGS. 18A-18D, the gate structure is recessed to form a recess 95 directly over the gate structure and between opposing portions of the gate spacers 86 and the gate seal spacers 80 (if present). In some embodiments, the gate structure is recessed by an anisotropic dry etch process. For example, the etching process may include a dry etch process using reaction gas(es) that selectively etch the gate dielectric 92 and the gate electrode 94 with little or no etching of the first ILD 88 or the gate seal spacers 80 (if present).

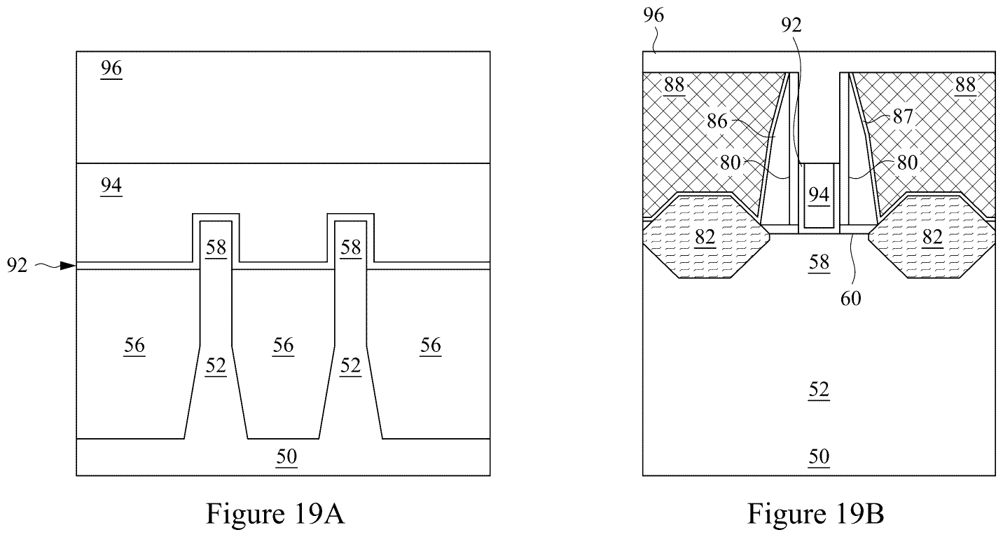

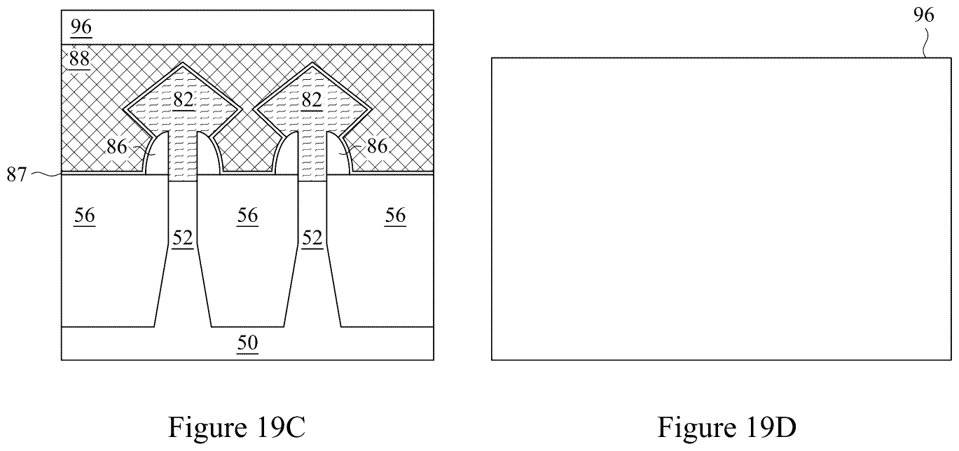

In FIGS. 19A-19D, a gate mask layer 96 is formed over the gate structure and the first ILD 88. The gate mask layer 96 comprises one or more layers of dielectric material, such as silicon nitride, silicon oxynitride, silicon carbide, the like, or a combination thereof. The gate mask layer 96 fills the recess 95 and may be disposed between opposing portions of the gate spacers 86 and the gate seal spacers 80 (if present).

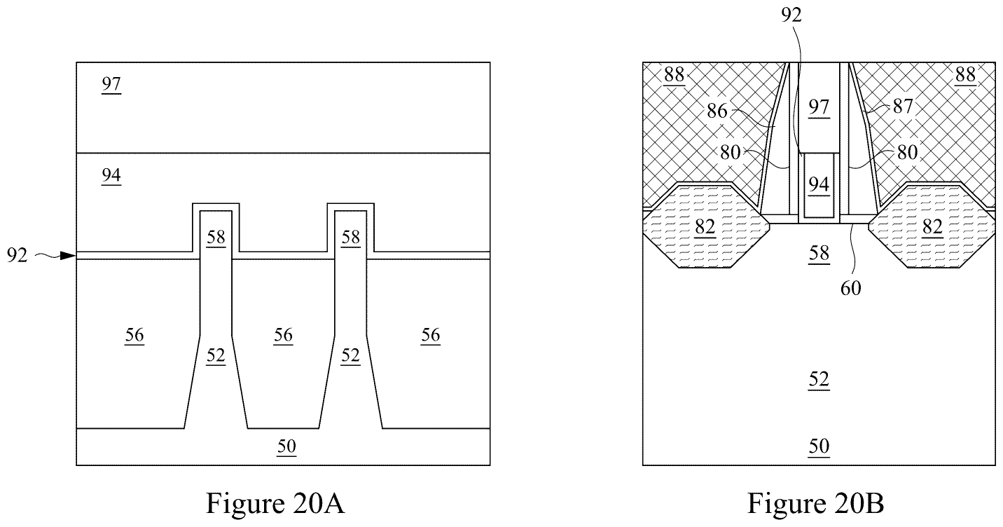

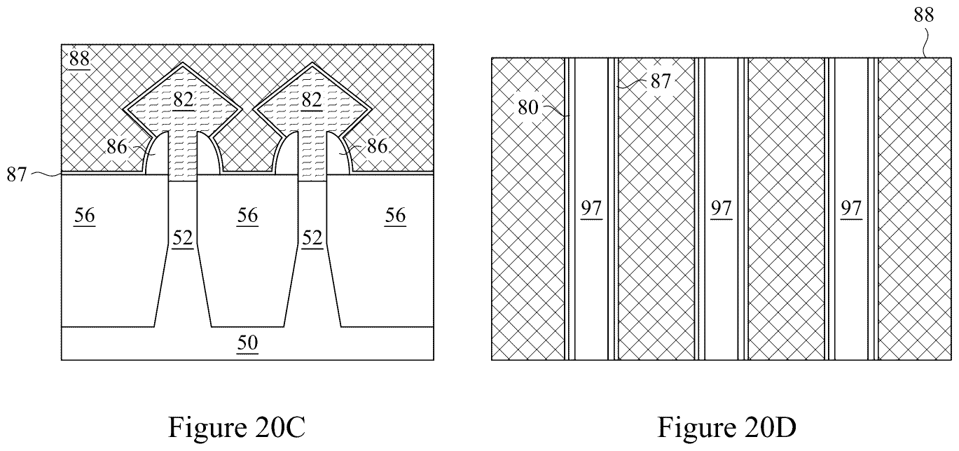

In FIGS. 20A-20D, a planarization process removes excess portions of the gate mask layer 96 extending over the first ILD 88. The remaining portion of the gate mask layer 96 filling the recess 95 (see above, FIGS. 18A-18D) forms a gate mask 97 over the gate structure (including the gate dielectric 92 and the corresponding gate electrode 94).

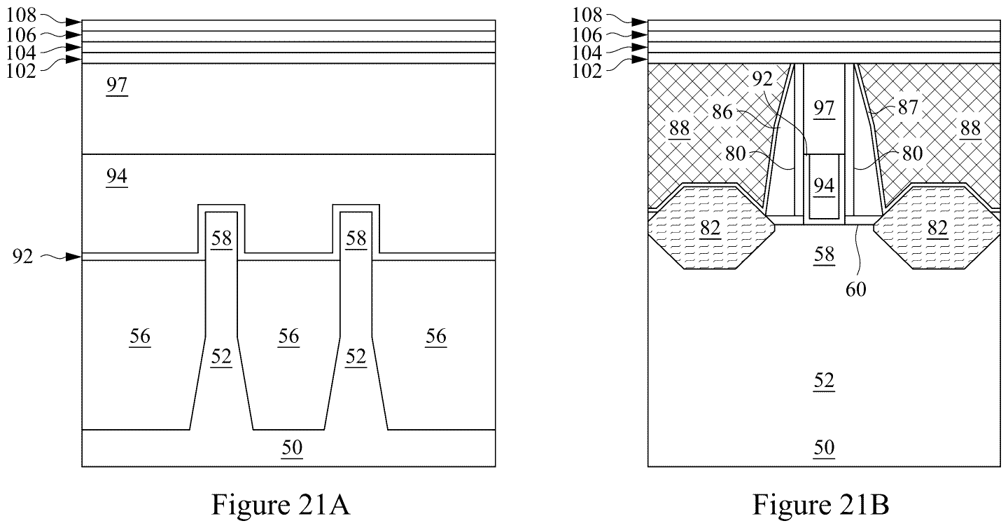

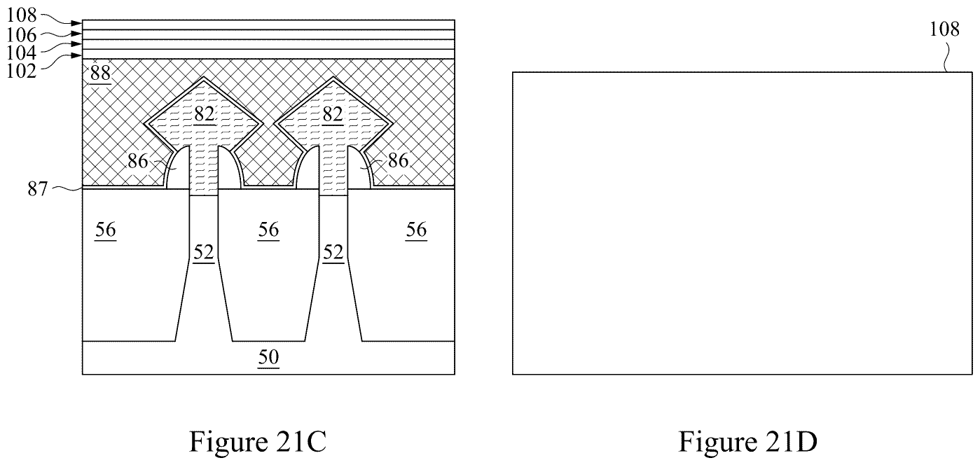

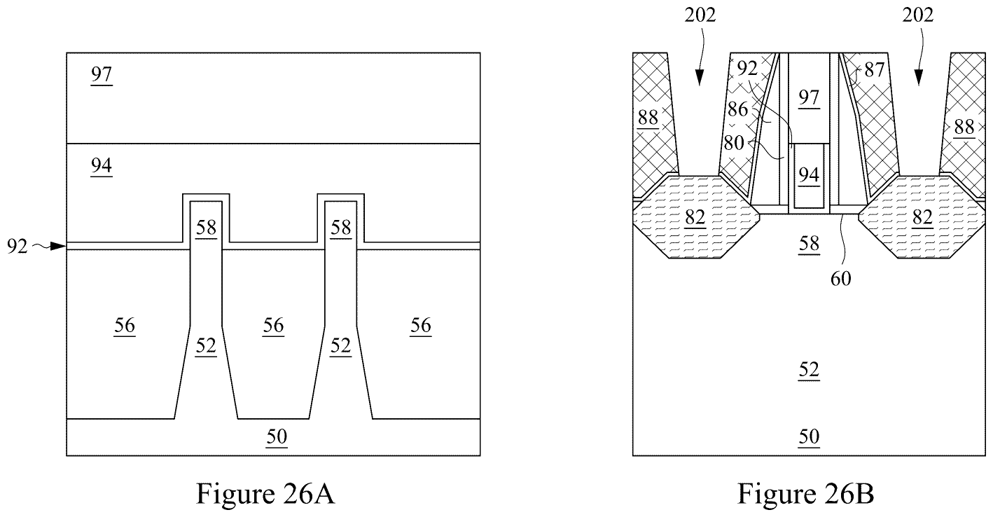

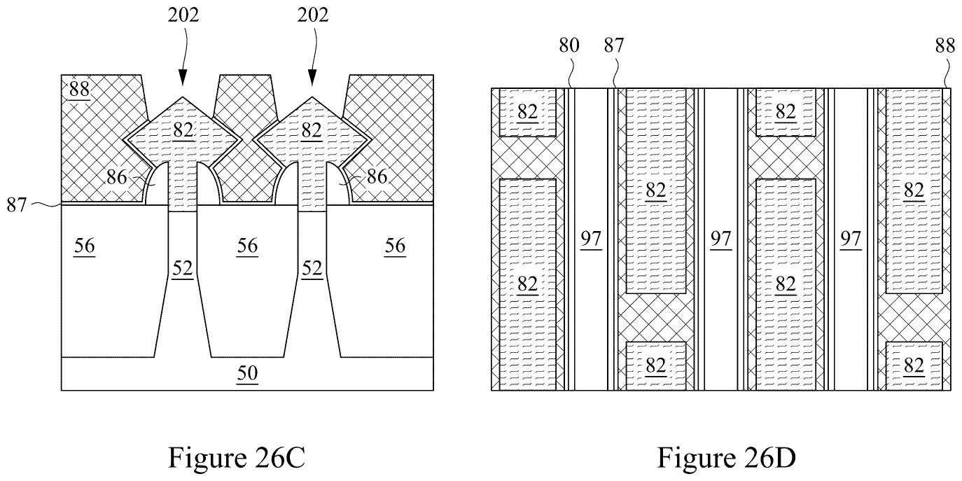

In FIGS. 21A-21D, one or more mask layers are formed over the first ILD 88 and the gate mask 97. The mask layers will be used to pattern openings for subsequently formed contacts to the source/drain regions 82 (see below, FIGS. 26A-28D). In some embodiments, the one or more mask layers comprise a dielectric layer 102, a first hard mask layer 104, a second hard mask layer 106, and a patterning layer 108.

The dielectric layer 102 is formed over the first ILD 88 and the gate mask 97. The dielectric layer 102 is used to pattern openings for subsequently formed contacts to the source/drain regions 82 (see below, FIGS. 26A-28D). In some embodiments, portions of the dielectric layer 102 remain on the first ILD 88 after subsequent processing steps. Because of this, it is advantageous for the dielectric layer 102 to be a low-k dielectric material with a dielectric constant k in a range of 2.0 to 3.5, which is lower than the dielectric constant of silicon dioxide (k=3.9). The dielectric layer 102 having a dielectric constant k in a range of 2.0 to 3.5 may decrease capacitance of a resulting device, which is advantageous for increasing device response time. The dielectric layer 102 having a dielectric constant k less than 2.0 may be disadvantageous because it may lead to the film having poor quality and low hardness, decreasing reliability of the dielectric layer 102.

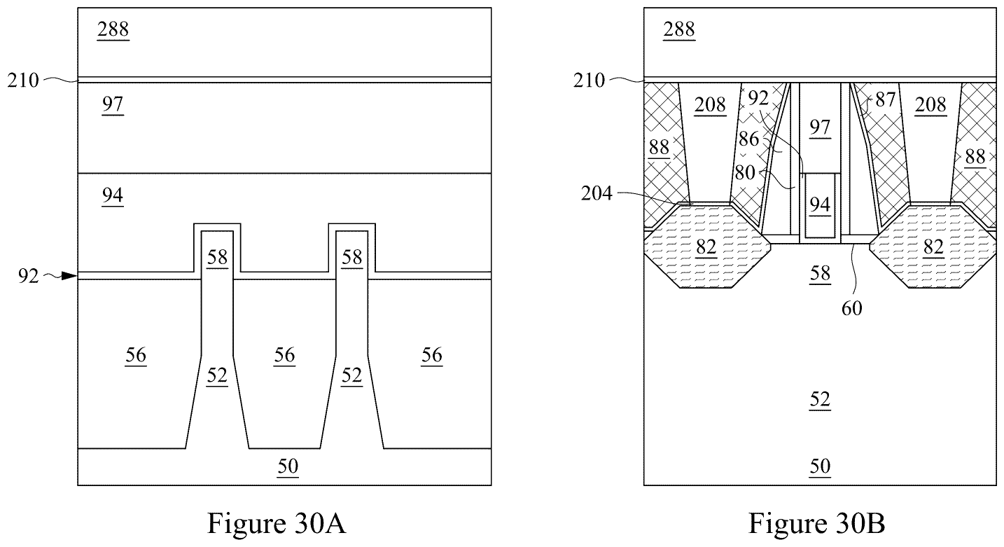

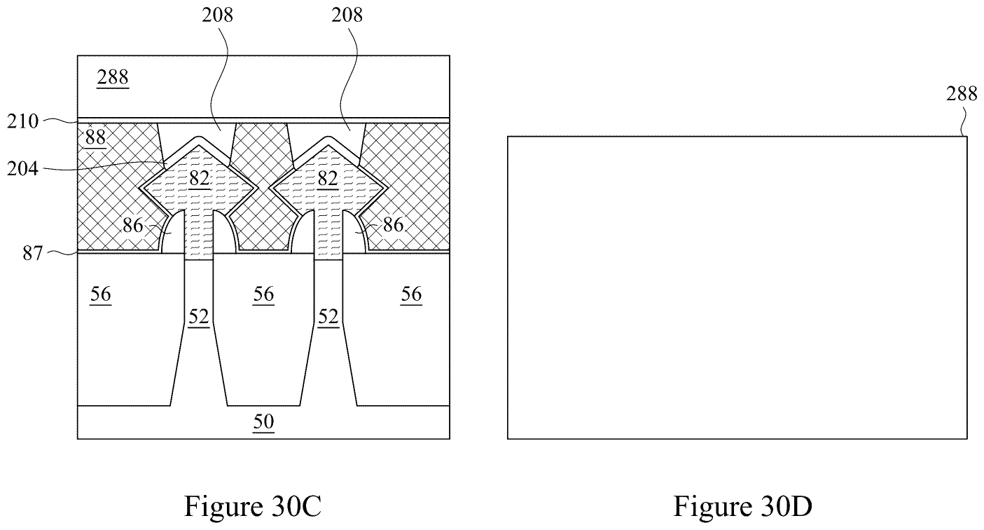

In some embodiments, the dielectric layer 102 is formed of similar materials and by similar methods as the first ILD 88 as described above with respect to FIGS. 12A-12D. As a first example, the dielectric layer 102 is a low-k dielectric material with a dielectric constant k in a range of 2.0 to 3.5 and comprises boron nitride, silicon dioxide comprising Si—CH₃ bonds, the like, or a combination thereof. As a second example, the dielectric layer 102 has a dielectric constant of 3.9 or greater and comprises silicon oxide, silicon dioxide, phospho-silicate glass (PSG), boro-silicate glass (BSG), boron-doped phospho-silicate glass (BPSG), undoped silicate glass (USG), or the like. In some embodiments, the first ILD 88 and the dielectric layer 102 are both low-k dielectric materials with a dielectric constant k in a range of 2.0 to 3.5. In some embodiments, the first ILD 88 is a low-k dielectric material with a dielectric constant k in a range of 2.0 to 3.5 and the dielectric layer 102 is a dielectric material with a dielectric constant k of 3.9 or greater. In some embodiments, the first ILD 88 is a dielectric material with a dielectric constant k of 3.9 or greater and the dielectric layer 102 is a low-k dielectric material with a dielectric constant k in a range of 2.0 to 3.5. In some embodiments as discussed further below with respect to FIGS. 30A-30D, the first ILD 88 and the dielectric layer 102 are both dielectric materials with a dielectric constant k of 3.9 or greater.

The first hard mask layer 104 is formed over the dielectric layer 102. In some embodiments, the first hard mask layer 104 is formed of a mask material such as tungsten carbide, titanium nitride, tantalum nitride, metal oxide, the like, or a combination thereof, which has a strong physical modulus for subsequent patterning of openings (see below, FIGS. 26A-26D). The first hard mask layer 104 may be formed using PECVD, Atomic Layer Deposition (ALD), CVD, Physical Vapor Deposition (PVD), or the like.

The second hard mask layer 106 is formed over the first hard mask layer 104. The second hard mask layer 106 may be formed of an oxide such as titanium oxide, silicon oxide, a combination thereof, or the like, which may be formed by CVD, ALD, or the like. In some embodiments, the second hard mask layer 106 is formed of silicon oxide using TEOS or SiH₄ as a precursor.

The patterning layer 108 is formed over the second hard mask layer 106. In some embodiments, the patterning layer 108 comprises a patternable material such as amorphous silicon, boron doped Si, the like, or a combination thereof, which is deposited and then patterned (see below, FIGS. 26A-26D). In other embodiments, the patterning layer 108 may comprise SiN, SiO₂, or the like.

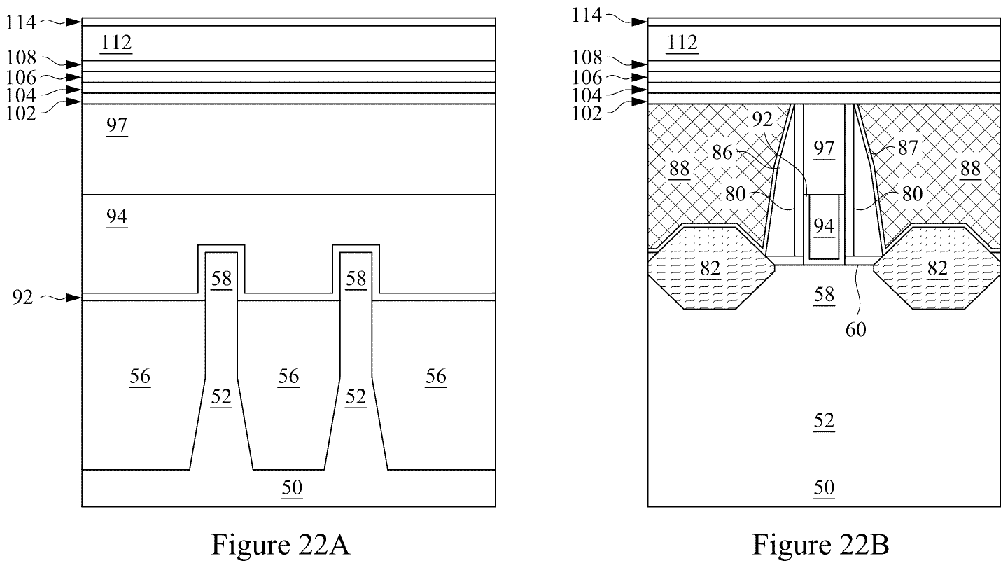

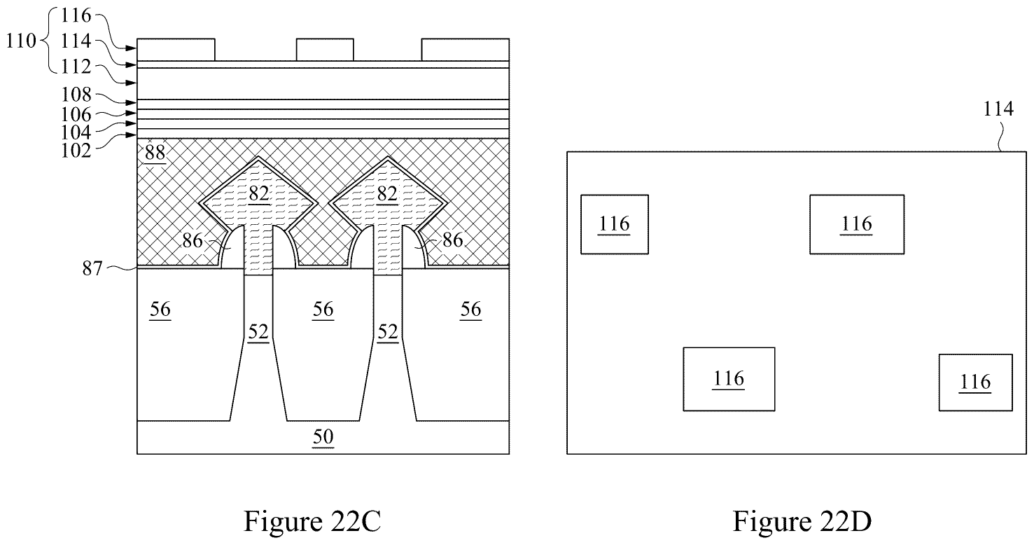

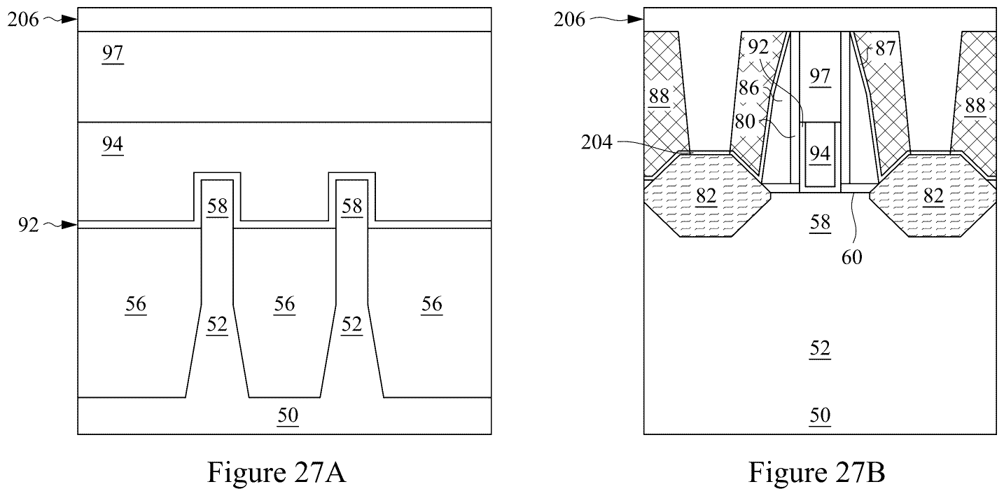

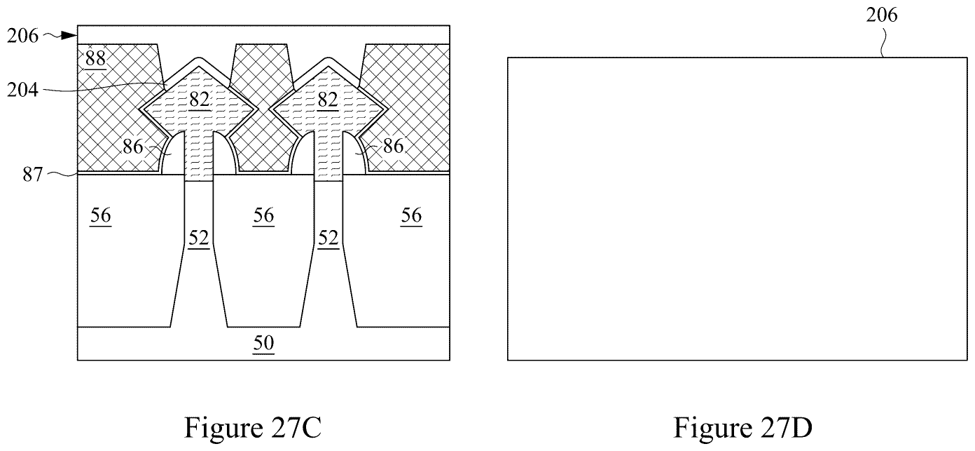

FIGS. 22A-26D illustrate an example patterning process for forming openings 202 through the first ILD 88 for subsequently formed source/drain contacts (see below, FIGS. 27A-27D), in accordance with some embodiments. The example patterning process includes forming and patterning two photosensitive masks in order to pattern the one or more mask layers (e.g., the dielectric layer 102, the first hard mask layer 104, the second hard mask layer 106, and the patterning layer 108). However, any suitable patterning process may be used to form the openings 202.

In FIGS. 22A-22D, a first photosensitive mask 110 is formed over the patterning layer 108. The first photosensitive mask 110 may be any acceptable photoresist, such as a single-layer photoresist, a bi-layer photoresist, a tri-layer photoresist, or the like. In the illustrated embodiment, the first photosensitive mask 110 is a tri-layer photoresist including a first bottom layer 112, a first middle layer 114, and a first top layer 116. In some embodiments, the first bottom layer 112 is a bottom anti-reflective coating (BARC) layer, the first middle layer 114 is formed of a silicon-containing film, and the first top layer 116 is formed of a photosensitive material. However, any suitable materials may be used for the first photosensitive mask 110. The first top layer 116 is patterned with remaining portions of the first top layer 116 overlying portions of the first ILD 88 between adjacent source/drain regions 82.

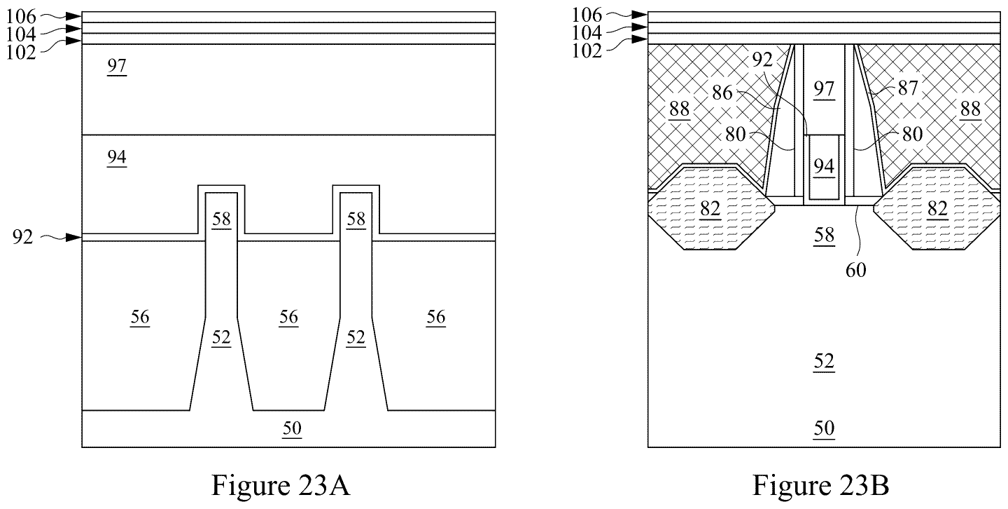

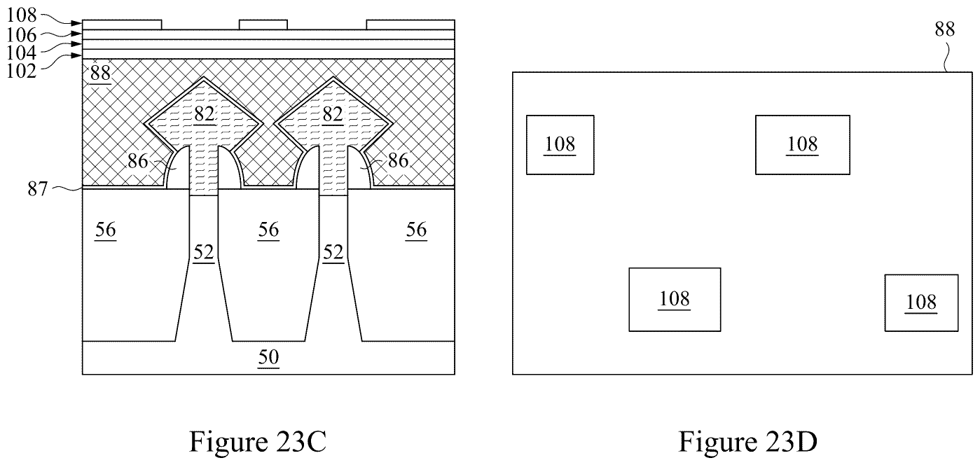

In FIGS. 23A-23D, the first photosensitive mask 110 is used as an etching mask to etch and pattern the patterning layer 108, thus forming masks that will be used in subsequent etching processes to mask portions of the first ILD 88 between adjacent source/drain regions 82. One or more layers of the first photosensitive mask 110 may be consumed in the etching process, or may be removed after the etching process. In some embodiments, the first photosensitive mask 110 is removed by an ashing process followed by a wet clean process. After the etching process and the removal of the first photosensitive mask 110, remaining portions of the patterning layer 108 can have a reduced thickness. Alternatively, the thickness of the patterning layer 108 may be substantially unchanged by the etching process.

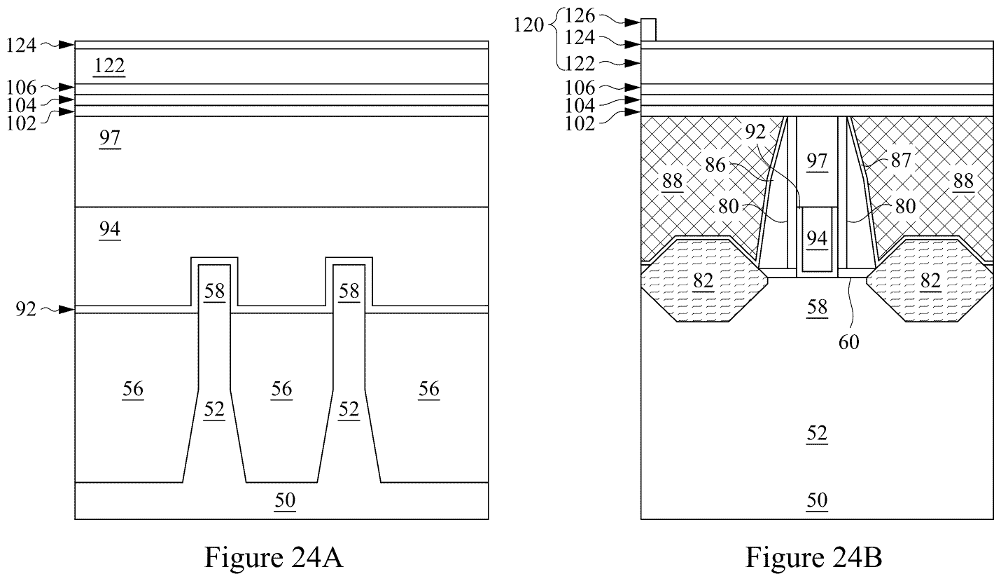

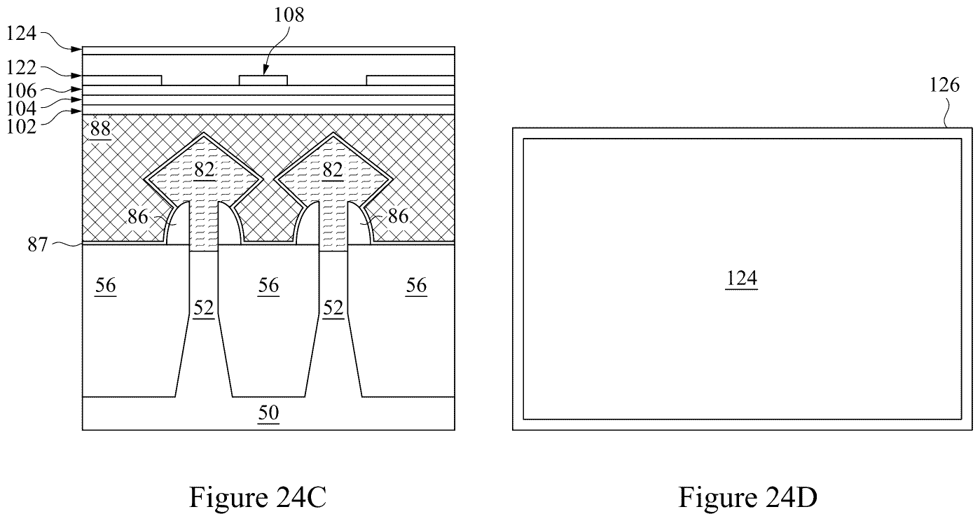

In FIGS. 24A-24D, a second photosensitive mask 120 is formed over the second hard mask layer 106 and remaining portions of the patterning layer 108. The second photosensitive mask 120 may be any acceptable photoresist, such as a single-layer photoresist, a bi-layer photoresist, a tri-layer photoresist, or the like. In the illustrated embodiment, the second photosensitive mask 120 is a tri-layer photoresist including a second bottom layer 122, a second middle layer 124, and a second top layer 126. The second photosensitive mask 120 may be formed with similar materials as the first photosensitive mask 110 as described above with respect to FIGS. 22A-22D. The second top layer 126 is patterned with remaining portions of the second top layer 126 overlying portions of the first ILD 88 that are adjacent to source/drain regions 82 opposite the gate structures.

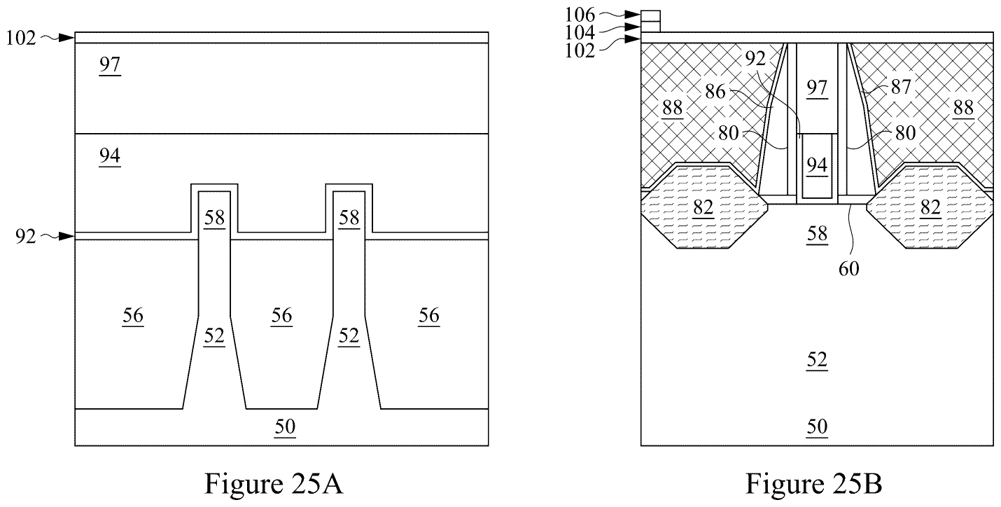

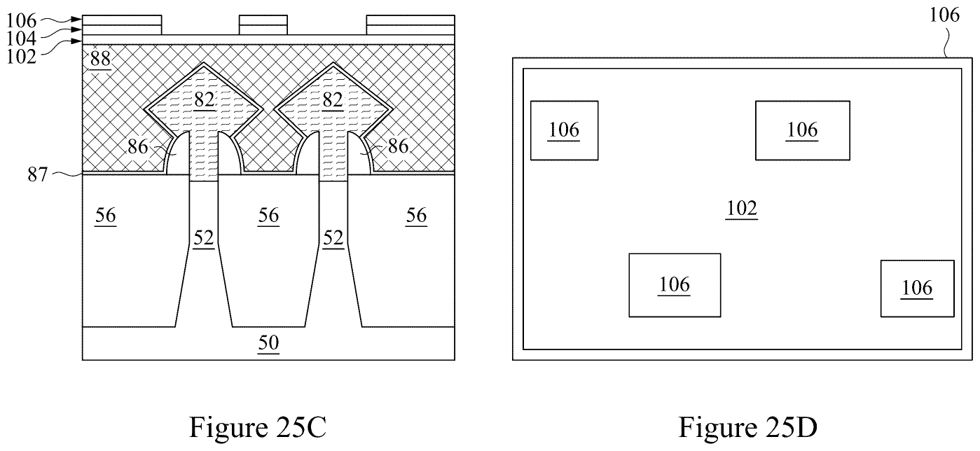

In FIGS. 25A-25D, the second photosensitive mask 120 and remaining portions of the patterning layer 108 are used as an etching mask to etch and pattern the first hard mask layer 104 and the second hard mask layer 106, thus forming masks that will be used in subsequent etching processes to mask portions of the first ILD 88 adjacent to source/drain regions 82. One or more layers of the second photosensitive mask 120 and remaining portions of the patterning layer 108 may be consumed in the etching process, or may be removed after the etching process. In some embodiments, the second photosensitive mask 120 is removed by an ashing process followed by a wet clean process. After the etching process and the removal of the second photosensitive mask 120 and remaining portions of the patterning layer 108, remaining portions of the second hard mask layer 106 can have a reduced thickness. Alternatively, the thickness of the second hard mask layer 106 may be substantially unchanged by the etching process.

In FIGS. 26A-26D, openings 202 for subsequently formed source/drain contacts (see below, FIGS. 27A-27D) are formed through the first ILD 88. In some embodiments, to transfer the openings in the remaining portions of the first hard mask layer 104 and the second hard mask layer 106, one or more anisotropic etching processes, such as one or more anisotropic plasma etching processes, are performed. The remaining portions of the first hard mask layer 104 mask portions of the first ILD 88 between adjacent source/drain regions 82 or adjacent to source/drain regions 82 opposite a gate structure. The one or more anisotropic plasma etching processes may be reactive-ion etching (RIE) processes. The remaining portions of the first hard mask layer 104, the second hard mask layer 106, and the dielectric layer 102 are consumed by the etching processes or otherwise removed from the top surface of the first ILD 88. In some embodiments, portions of the dielectric layer 102 remain on top surfaces of the first ILD 88. The remaining openings 202 expose top surfaces of the source/drain regions 82.

In FIGS. 27A-27D, silicide regions 204 are formed on exposed surfaces of the source/drain regions 82 and the openings 202 are filled with a conductive material 206. In some embodiments, the silicide regions 204 are formed by first depositing a metal (not shown) capable of reacting with the semiconductor materials of the underlying epitaxial source/drain regions 82 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 82, then performing a thermal anneal process to form the silicide regions 204. The un-reacted portions of the deposited metal are then removed, e.g., by an etching process. Although silicide regions 204 are referred to as silicide regions, silicide regions 204 may also be germanide regions, or silicon germanide regions (e.g., regions comprising silicide and germanide).

Next, the openings 202 are filled to form contacts electrically coupled to the source/drain regions 82 through the silicide regions 204. A liner (not shown), such as a diffusion barrier layer, an adhesion layer, or the like, and a conductive material 206 are formed in the openings 202. The liner may include titanium, titanium nitride, tantalum, tantalum nitride, or the like. The conductive material 206 may be copper, a copper alloy, silver, gold, tungsten, ruthenium, cobalt, aluminum, nickel, or the like. The conductive material 206 may extend over top surfaces of the first ILD 88. The conductive material 206 may be formed by CVD, PVD, electroless plating, the like, or a combination thereof.

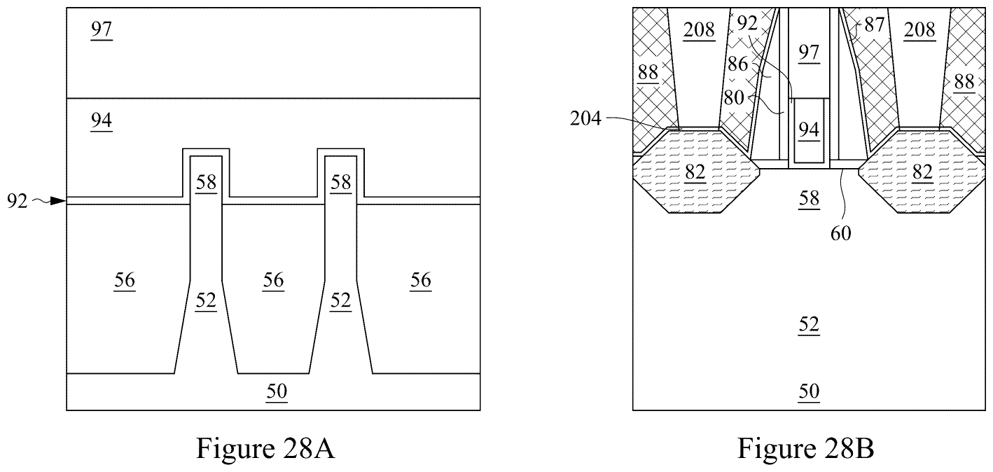

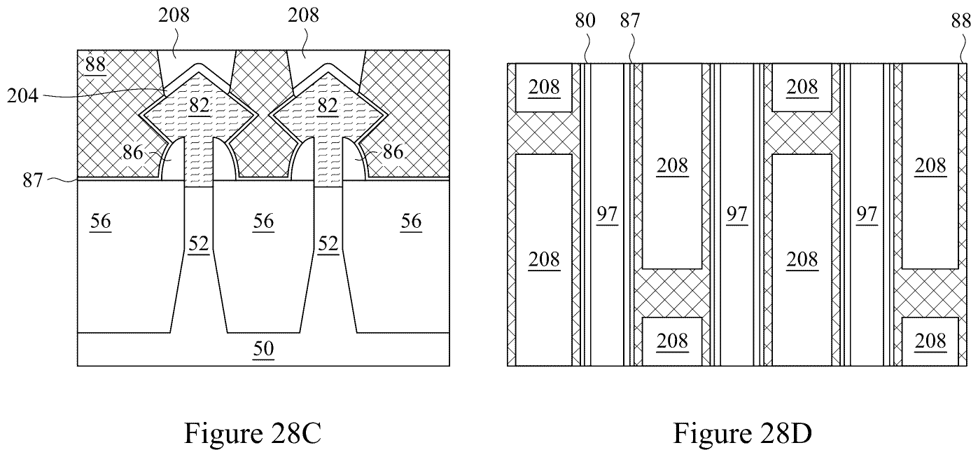

In FIGS. 28A-28D, top portions of the conductive material 206 are removed by a planarization process, such as a CMP. Remaining portions of the conductive material 206 in the openings 202 (see above, FIGS. 26B-26C) form source/drain contacts 208. The source/drain contacts 208 are physically and electrically coupled to the epitaxial source/drain regions 82. Although shown as being formed in the same cross-sections, it should be appreciated that each of the source/drain contacts 208 may be formed in different cross-sections, which may avoid shorting of the source/drain contacts 208.

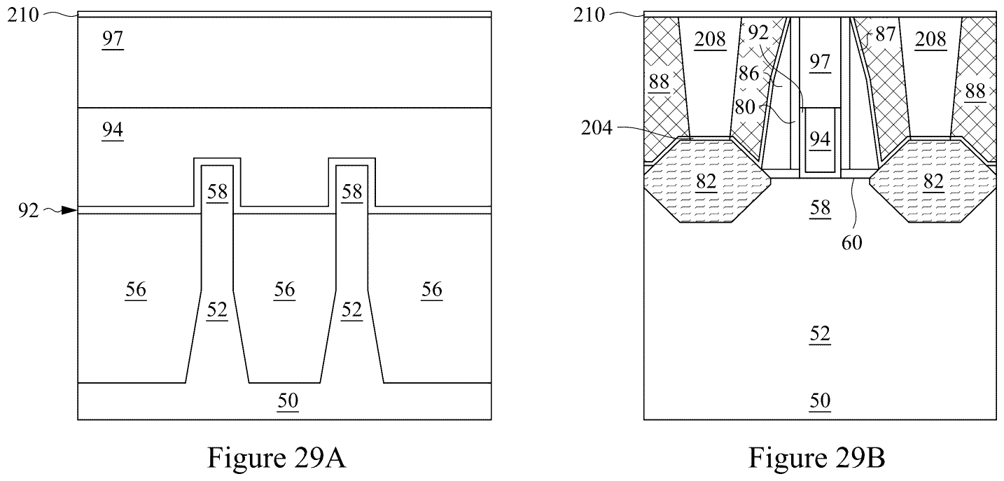

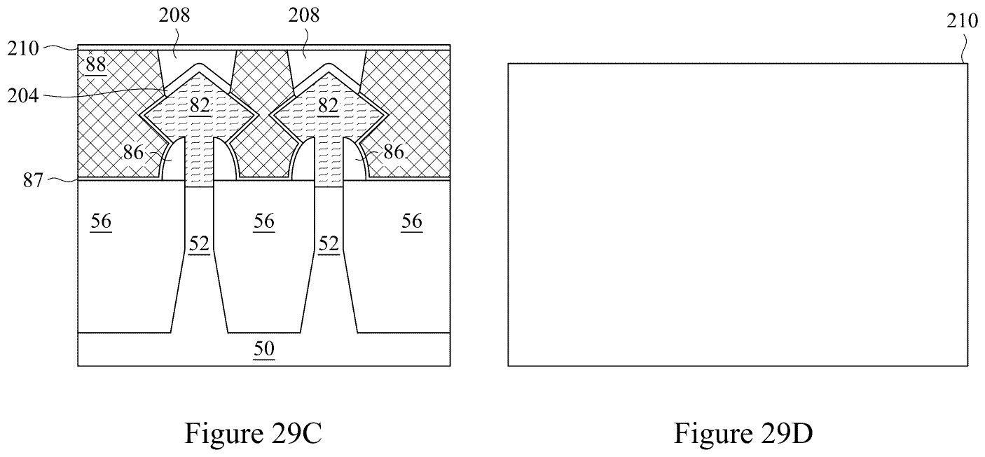

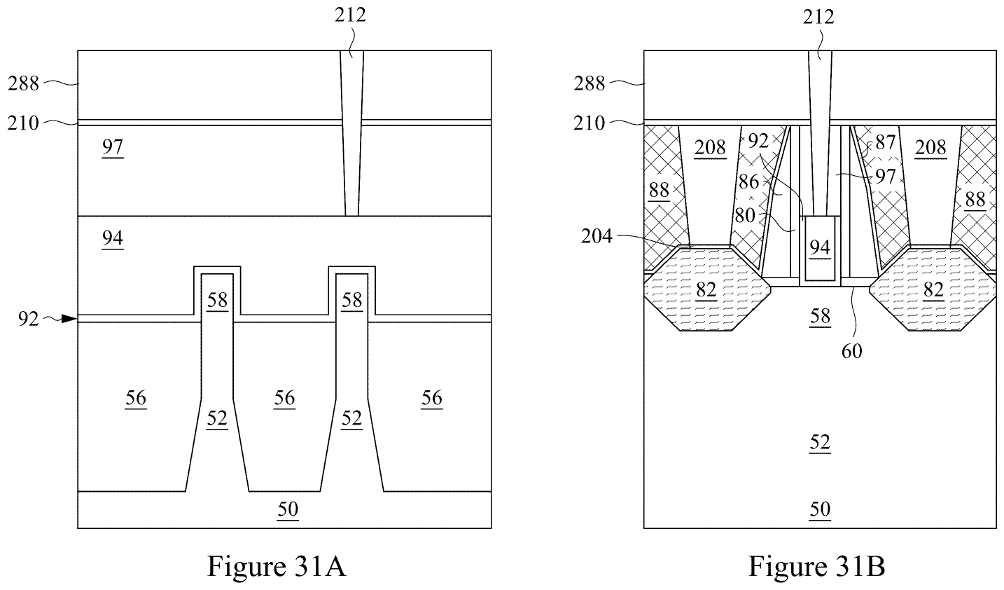

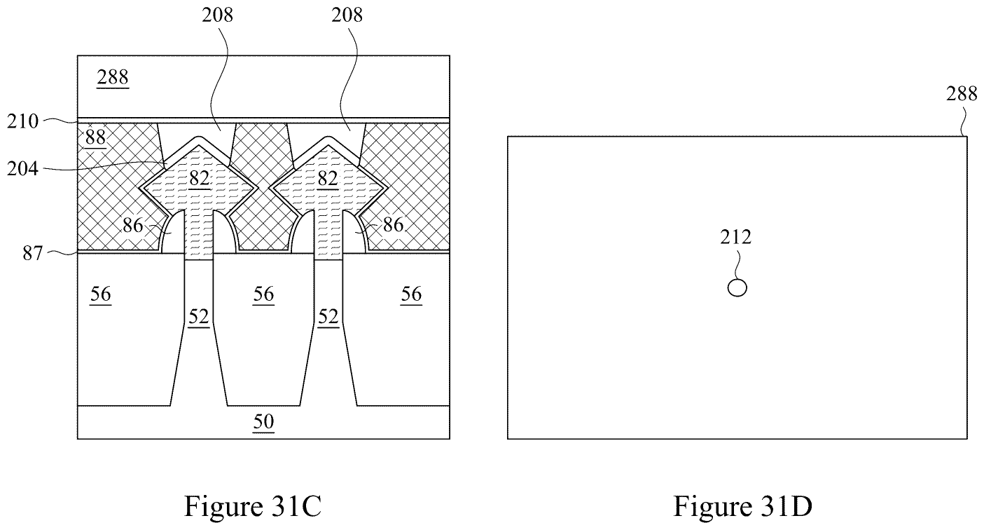

In FIGS. 29A-29D, an etch stop layer (ESL) 210 is formed over the structure illustrated in FIGS. 28A-28D, including the first ILD 88, the CESL 87, the source/drain contacts 208, the gate mask 97, and the gate spacers 86 (including the gate seal spacers 80, if present). The ESL 210 may be used to control subsequent etching processes to form openings for conductive contacts coupled to the gate electrode 94 and the source/drain contacts 208 (see below, FIGS. 31A-31D). The ESL 210 may comprise a dielectric material, such as silicon nitride, silicon oxide, silicon oxynitride, silicon carbide, silicon oxycarbide, silicon oxycarbonitride, or the like, having a lower etch rate than the material of the subsequently formed second ILD 288 (see below, FIGS. 30A-30D).

In FIGS. 30A-30D, a second ILD 288 is formed over the ESL 210. The second ILD 288 electrically isolates subsequently formed conductive features, e.g. conductive contacts coupled to the gate electrode 94 and the source/drain contacts 208 (see below, FIGS. 31A-31D). In some embodiments, the second ILD 288 is a low-k dielectric material with a dielectric constant k in a range of 2.0 to 3.5, which is lower than the dielectric constant of silicon dioxide (k=3.9). The second ILD 288 having a dielectric constant k in a range of 2.0 to 3.5 may decrease capacitance of a resulting device, which is advantageous for increasing device response time. The second ILD 288 having a dielectric constant k less than 2.0 may be disadvantageous because it may lead to the film having poor quality and low hardness, decreasing reliability of the second ILD 288.

In some embodiments, the second ILD 288 is formed of similar materials and by similar methods as the first ILD 88 as described above with respect to FIGS. 12A-12D. As a first example, the second ILD 288 is a low-k dielectric material with a dielectric constant k in a range of 2.0 to 3.5 and comprises boron nitride, silicon dioxide comprising Si—CH₃ bonds, the like, or a combination thereof. As a second example, the second ILD 288 has a dielectric constant of 3.9 or greater and comprises silicon oxide, silicon dioxide, phospho-silicate glass (PSG), boro-silicate glass (BSG), boron-doped phospho-silicate glass (BPSG), undoped silicate glass (USG), or the like. In some embodiments, the first ILD 88 (and/or remaining portions of the dielectric layer 102, if present) and the second ILD 288 are both low-k dielectric materials with a dielectric constant k in a range of 2.0 to 3.5. In some embodiments, the first ILD 88 (and/or remaining portions of the dielectric layer 102, if present) is a low-k dielectric material with a dielectric constant k in a range of 2.0 to 3.5 and the second ILD 288 is a dielectric material with a dielectric constant k of 3.9 or greater. In some embodiments, the first ILD 88 (and/or remaining portions of the dielectric layer 102, if present) is a dielectric material with a dielectric constant k of 3.9 or greater and the second ILD 288 is a low-k dielectric material with a dielectric constant k in a range of 2.0 to 3.5. In some embodiments, the first ILD 88 (and/or remaining portions of the dielectric layer 102, if present) and the second ILD 288 are both dielectric materials with a dielectric constant k of 3.9 or greater.

In FIGS. 31A-31D, a gate contact 212 is formed through the second ILD 288 to electrically couple with the gate electrode 94 in accordance with some embodiments. An opening for the gate contact 212 is formed through the second ILD 288, the ESL 210, and the gate mask 97. The opening may be formed using acceptable photolithography and etching techniques. A liner (not shown), such as a diffusion barrier layer, an adhesion layer, or the like, and a conductive material is formed in the opening. The liner may include titanium, titanium nitride, tantalum, tantalum nitride, or the like. The conductive material may be copper, a copper alloy, silver, gold, tungsten, ruthenium, cobalt, aluminum, nickel, or the like. A planarization process, such as a CMP, may be performed to remove excess material from a surface of the second ILD 288. The remaining liner and conductive material form the gate contact 212 in the opening. The gate contact 212 is physically and electrically coupled to the gate electrode 94.

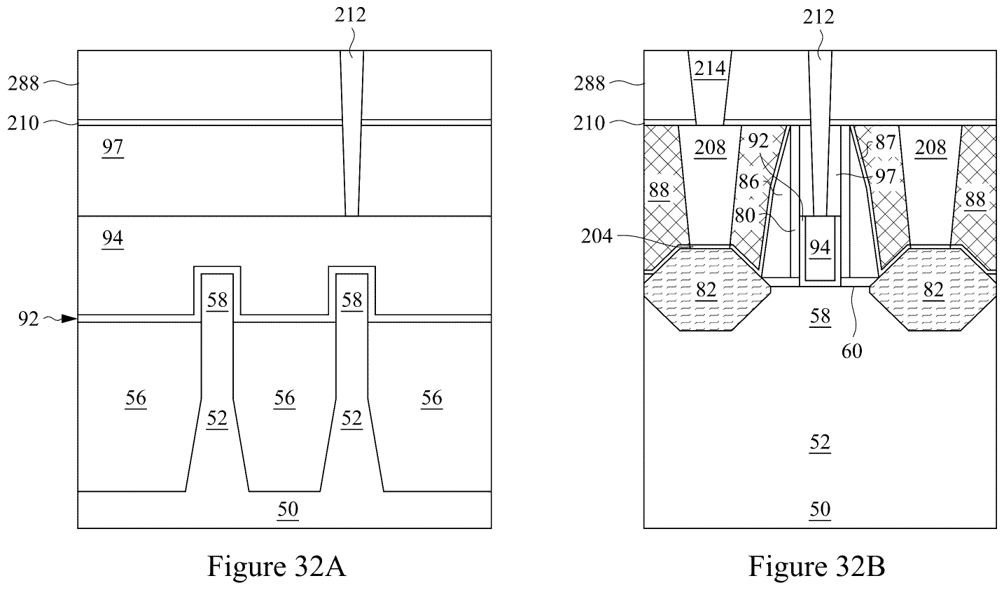

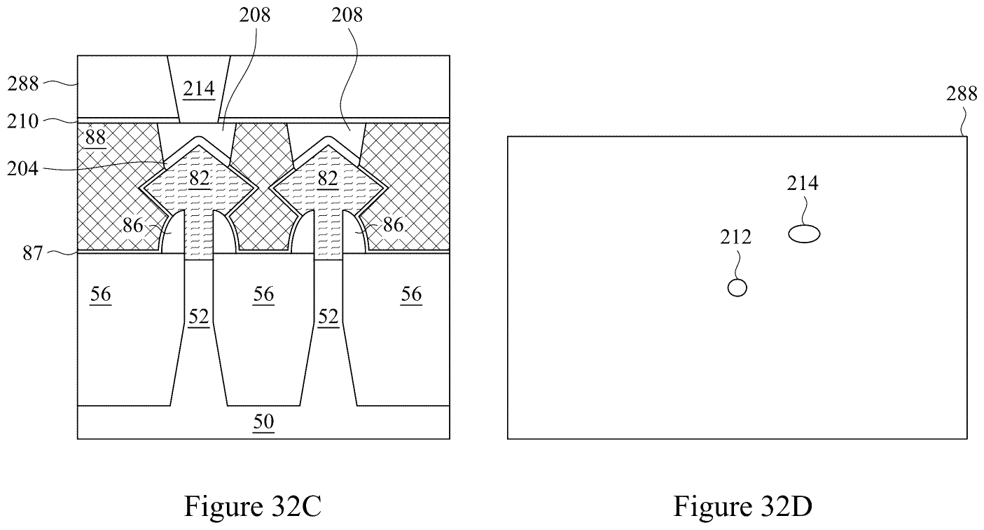

In FIGS. 32A-32D, conductive vias 214 are formed through the second ILD 288 to electrically couple with the source/drain contacts 208 in accordance with some embodiments. Openings for the conductive vias 214 are formed through the second ILD 288 and the ESL 210. The openings may be formed using acceptable photolithography and etching techniques. A liner (not shown), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 288. The remaining liner and conductive material form the conductive vias 214 in the openings. The conductive vias 214 and gate contact 212 may be formed in different processes, or may be formed in the same process. Although shown as being formed in the same cross-sections, it should be appreciated that each of the conductive vias 214 and gate contact 212 may be formed in different cross-sections, which may avoid shorting of the contacts.

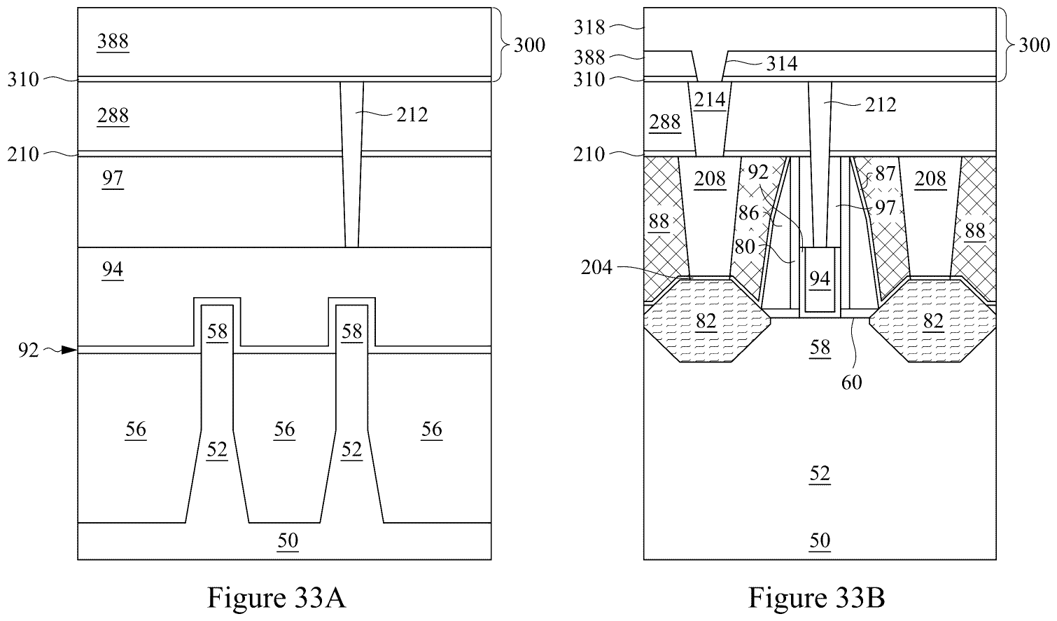

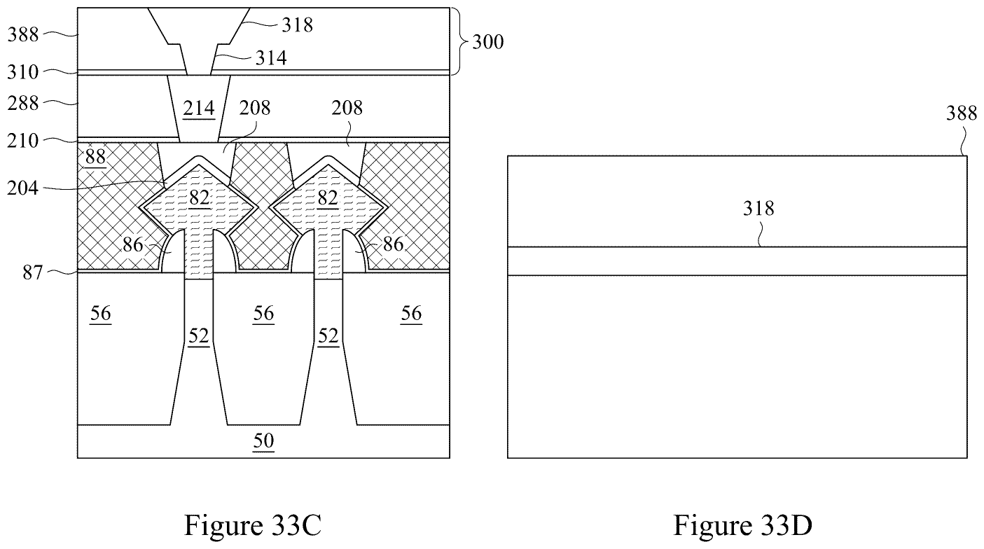

FIGS. 33A-33D illustrate the formation of an interconnect level 300 over the second ILD 288 and conductive vias 214. The interconnect level 300 comprises conductive vias 314 and/or conductive lines 318 embedded in an intermetal dielectric (IMD) 388. The interconnect level 300 may be the bottom interconnect level of a subsequently formed interconnect structure. Generally, vias conduct current vertically and are used to electrically connect two conductive features located at vertically adjacent levels, whereas lines conduct current laterally and are used to distribute electrical signals and power within one interconnect level. In the interconnect level 300, conductive vias 314 connect conductive vias 214 to conductive lines 318 and, at subsequent interconnect levels (not shown), vias connect lines on a level below the vias to lines above the vias. In some embodiments, the structures of the various interconnect levels (e.g., the interconnect level 300 and subsequent interconnect levels formed above the interconnect level 300) may be similar.

An ESL 310 may be formed over the second ILD 288 and conductive vias 214. The ESL 310 is used for controlling subsequent etching processes to form a via opening for the conductive via 314. In some embodiments, the ESL 310 is formed of similar materials and by similar methods as the CESL 87 as described above with respect to FIGS. 11A-11D.

The IMD 388 is formed over the ESL 310 to support and insulate subsequently formed electrically conductive vias 314 and conductive lines 318 from each other. In some embodiments, the IMD 388 is a low-k dielectric material with a dielectric constant k in a range of 2.0 to 3.5, which is lower than the dielectric constant of silicon dioxide (k=3.9). The IMD 388 having a dielectric constant k in a range of 2. 0 to 3.5 may decrease capacitance of a resulting device, which is advantageous for increasing device response time. The IMD 388 having a dielectric constant k less than 2.0 may be disadvantageous because it may lead to the film having poor quality and low hardness, decreasing reliability of the IMD 388.

Still referring to FIGS. 33A-33D, the conductive vias 314 and conductive lines 318 may be formed using, for example, a dual damascene process flow. Openings for vias and lines are formed in the IMD 388 with appropriate photolithography and etching techniques. The openings for vias may be vertical holes extending through the IMD 388 to expose a top conductive surface of the conductive vias 214, and the openings for lines may be longitudinal trenches formed in an upper portion of the IMD 388. The openings may be formed using either a via-first process or a via-last process.

Several conductive materials may be deposited to fill the holes and trenches forming the conductive vias 314 and conductive lines 316 of the interconnect level 300. For example, the holes and trenches may be first lined with one or more liners and then filled with a conductive fill layer. A conductive diffusion barrier liner may be formed over sidewalls and bottom surfaces of the holes and trenches. Any excess conductive material over the IMD 388 outside of the openings may be removed by a planarizing process (e.g., CMP) thereby forming a top surface comprising dielectric regions of IMD 388 that are substantially coplanar with conductive regions of conductive lines 318.

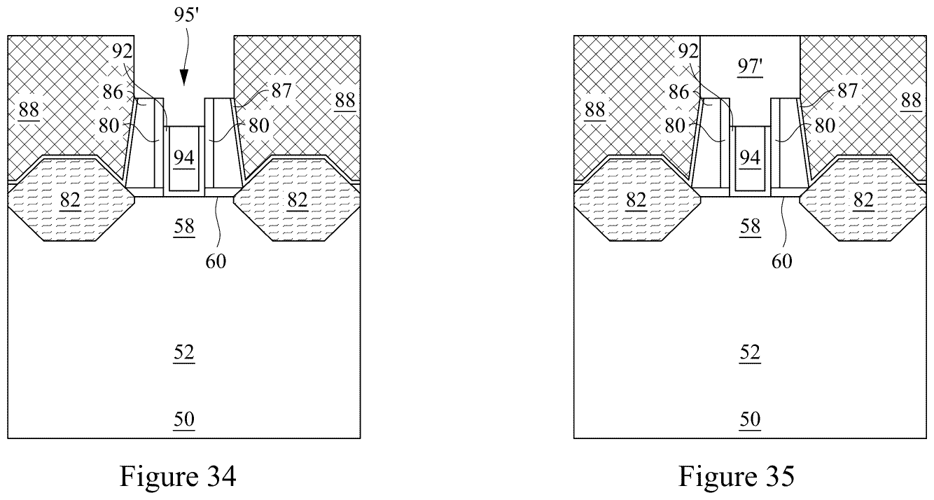

FIGS. 34 through 39 illustrate another embodiment s in which not only is the gate structure recessed (such as illustrated and discussed above with respect to FIGS. 18A-18D), but both the gate spacers and the gate structure are recessed so that a subsequently formed gate mask is formed over the gate spacers as well as the gate structure. FIGS. 34 through 39 are cross-sectional views illustrated along line B-B′in FIG. 1. The process of FIGS. 34 through 39 follows from the step of FIG. 17B (described above).

In FIG. 34, the gate structure (including a gate dielectric 92 and a corresponding gate electrode 94) and the gate spacers 86 (including gate seal spacers 80 if present) are recessed to form a recess 95′ over the gate structure and remaining portions of the gate spacers 86 and the gate seal spacers 80 (if present). A gate mask (see below, FIG. 35) is subsequently formed in the recess 95′. In some embodiments, the gate structure is recessed by one or more anisotropic dry etch process. For example, the etching process may include dry etch process(es) using reaction gas(es) that selectively etch the gate dielectric 92, the gate electrode 94, and the gate spacers 86 and the gate seal spacers 80 (if present) with little or no etching of the first ILD 88. In some embodiments, the gate structure is recessed to a greater depth than the gate spacers 86 and the gate seal spacers 80 (if present), so that top surfaces of the gate spacers 86 and the gate seal spacers 80 (if present) are above a top surface of the gate structure.

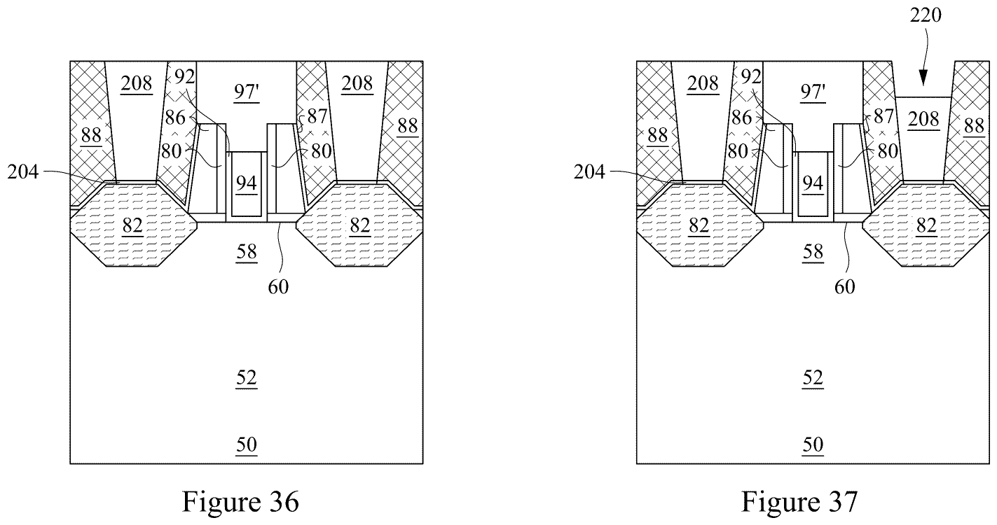

In FIG. 35, a gate mask 97′ is formed over the gate structure and remaining portions of the gate spacers 86 and the gate seal spacers 80 (if present). In some embodiments, the gate mask 97′ is formed of similar materials and by similar methods as the gate mask 97 as described above with respect to FIGS. 19A-20D. In some embodiments in accordance with FIG. 36, portions of the gate mask 97′ extend over the gate spacers 86 and the gate seal spacers 80 (if present), and a lower portion of the gate mask 97′ extends below top surfaces of the gate spacers 86 and the gate seal spacers 80 (if present).

In FIG. 36, silicide regions 204 and source/drain contacts 208 are formed on the source/drain regions 82.). In some embodiments, the silicide regions 204 and source/drain contacts 208 is formed of similar materials and by similar methods as described above with respect to FIGS. 27A-28D.

In FIG. 37, a source/drain contact 208 is recessed to form an opening 220 for a subsequently formed contact mask. In some embodiments, the opening 220 is recessed by one or more anisotropic dry etch processes. For example, the etching process may include dry etch process(es) using reaction gas(es) that selectively etch the source/drain contact 208 with little or no etching of the first ILD 88. Other source/drain contacts 208 may be masked during the formation of the opening 220 by suitable photolithography techniques.

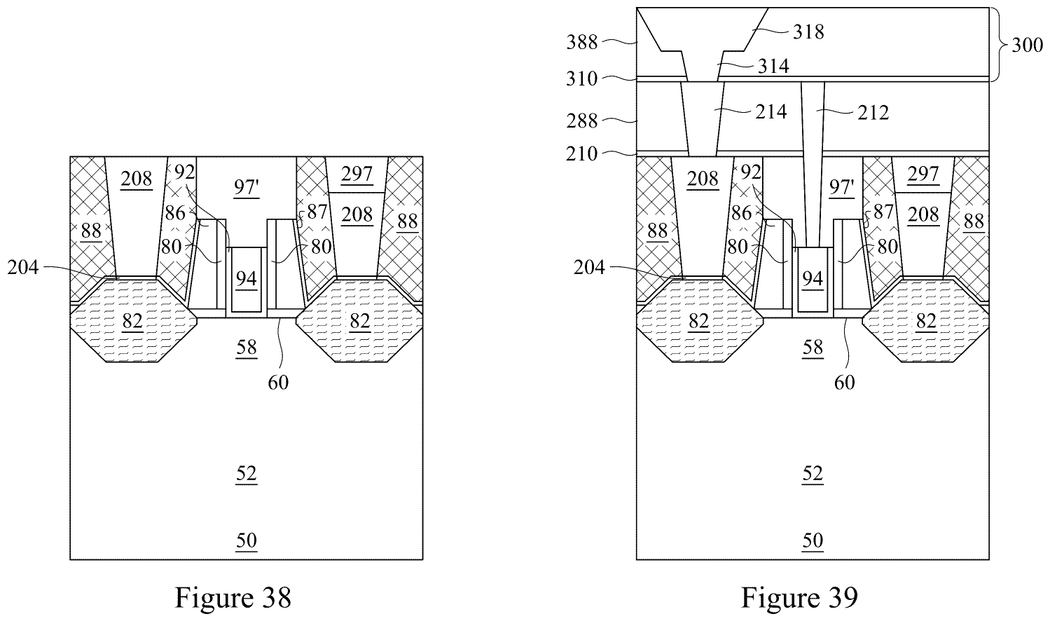

In FIG. 38, a contact mask 297 is formed in the opening 220 over the recessed source/drain contact 208. In some embodiments, the gate mask 97′ is formed of similar materials and by similar methods as the gate mask 97 as described above with respect to FIGS. 19A-20D.

FIG. 39 illustrates an embodiment following from FIG. 38. The structure of FIG. 39 may be formed by the steps described above with respect to FIGS. 29A-33D. In FIG. 39, one source/drain contact 208 is covered by a contact mask 297 and another source/drain contact 208 extends to a bottom surface of the ESL 210. A conductive via 214 electrically couples one of the source/drain contacts 208 with a conductive via 314 in an overlying interconnect layer 300. In some embodiments, another conductive via 214 is formed through the contact mask 297 to electrically couple with the source/drain contact 208 covered by the contact mask 297.

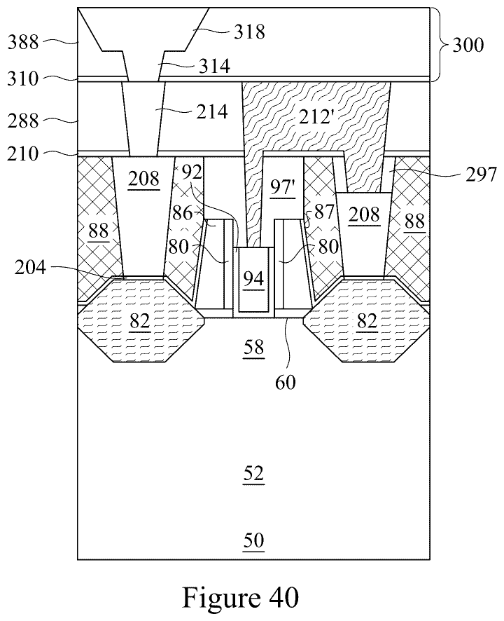

FIG. 40 illustrates an embodiment in which a butted contact 212′ is formed that is electrically coupled to the gate electrode 94 and a source/drain contact 208. In some embodiments, the butted contact 212′ is used to form circuitry, e.g. an SRAM cell, in which the contacts to the source/drain region 82 and to the gate electrode 94 are at a same voltage. The butted contact 212′ may be formed of similar materials and by similar methods as the gate contact 212 as described above with respect to FIGS. 31A-31D, except that the butted contact 212′ is also formed to couple with the source/drain contact 208. In some embodiments, the butted contact 212′ is formed through a contact mask 297 over the source/drain contact 208.

The disclosed FinFET embodiments could also be applied to nanostructure devices such as nanostructure (e.g., nanosheet, nanowire, gate-all-around, or the like) field effect transistors (NSFETs) or forksheet FETs. In an NSFET embodiment, the fins are replaced by nanostructures formed by patterning a stack of alternating layers of channel layers and sacrificial layers. Dummy gate structures and source/drain regions are formed in a manner similar to the above-described embodiments. After the dummy gate structures are removed, the sacrificial layers can be partially or fully removed in channel regions. The replacement gate structures are formed in a manner similar to the above-described embodiments, the replacement gate structures may partially or completely fill openings left by removing the sacrificial layers, and the replacement gate structures may partially or completely surround the channel layers in the channel regions of the NSFET devices. ILDs and contacts to the replacement gate structures and the source/drain regions may be formed in a manner similar to the above-described embodiments. A nanostructure device can be formed as disclosed in U.S. Pat. No. 9,647,071, which is incorporated herein by reference in its entirety. In forksheet FETs, both n-type devices and p-type devices are integrated in a same forksheet structure. Forksheet FETs include forksheet structures with dielectric walls that allow n-type devices and p-type devices to be formed close to one another, and allow gate structures for the devices to be physically and electrically coupled to one another. A forksheet device can be formed as disclosed in U.S. patent application Ser. No. 17/127,095, which is incorporated herein by reference in its entirety.

Embodiments may achieve advantages. For example, in some embodiments, one or more dielectric layers are formed with dielectric constants k in a range of 2. 0 to 3.5 to decrease capacitance of the devices comprising the one or more dielectric layers. This is advantageous for increasing device response time. The one or more dielectric layers may comprise boron nitride and/or silicon dioxide comprising Si—CH₃ bonds, and may be formed with capacitive coupling plasma (CCP) or inductive coupling plasma (ICP) techniques.

In accordance with an embodiment, a method for manufacturing a semiconductor device includes: forming a source/drain region on a semiconductor fin, the source/drain region being adjacent to a dummy gate; forming a first dielectric layer over the source/drain region and the dummy gate, the first dielectric layer having a dielectric constant of 3.5 or less, the first dielectric layer including boron nitride; and forming an opening by removing the dummy gate. In an embodiment, forming the first dielectric layer includes a plasma process using capacitive coupling plasma. In an embodiment, forming the first dielectric layer includes a plasma process using inductive coupling plasma. In an embodiment, forming the first dielectric layer includes using borazine as a process gas. In an embodiment, forming the first dielectric layer includes using boron trichloride and nitrogen as process gases. In an embodiment, the method further includes: depositing a gate structure in the opening; forming a first etch stop layer over the first dielectric layer and the gate structure; and forming a second dielectric layer over the first etch stop layer. In an embodiment, the method further includes: forming a second etch stop layer over the second dielectric layer, wherein the second dielectric layer has a dielectric constant of 3.5 or less, the second etch stop layer being in physical contact with the second dielectric layer; and forming a third dielectric layer over the second etch stop layer, wherein the third dielectric layer has a dielectric constant of 3.9 or greater, the third dielectric layer being in physical contact with the second etch stop layer. In an embodiment, the method further includes: forming a second etch stop layer over the second dielectric layer, wherein the second dielectric layer has a dielectric constant of 3.9 or greater; and forming a third dielectric layer over the second etch stop layer, wherein the third dielectric layer has a dielectric constant of 3.5 or less.

In accordance with another embodiment, a method for manufacturing a semiconductor device includes: forming a dummy gate over a semiconductor fin; forming a source/drain region on the semiconductor fin, the source/drain region being adjacent to the dummy gate; using diethoxymethylsilane and alpha-Terpinene as precursors to deposit a first dielectric layer over the dummy gate and the source/drain region, the first dielectric layer having a dielectric constant less than 3.5; and after depositing the first dielectric layer, forming a first opening by removing the dummy gate. In an embodiment, the method further includes: depositing a gate structure in the first opening; forming a second dielectric layer over the gate structure and the first dielectric layer; forming a second opening through the second dielectric layer and the first dielectric layer to the source/drain region; and filling the second opening with a source/drain contact. In an embodiment, the second dielectric layer has a dielectric constant of 3.5 or less. In an embodiment, the second dielectric layer has a dielectric constant of 3.9 or greater. In an embodiment, forming the second dielectric layer includes using diethoxymethylsilane and alpha-Terpinene as precursors. In an embodiment, forming the second dielectric layer includes using borazine or boron trichloride as a process gas. In an embodiment, forming the second opening further includes removing the second dielectric layer. In an embodiment, the method further includes forming an etch stop layer over the source/drain contact, the second dielectric layer, and the gate structure.

In accordance with yet another embodiment, a semiconductor device includes: a fin extending from a substrate; a gate structure over the fin; a source/drain region adjacent the gate structure; and a first dielectric layer over the fin, the first dielectric layer having a dielectric constant of 3.5 or less, the first dielectric layer including boron nitride, the first dielectric layer extending below a top surface of the gate structure. In an embodiment, the semiconductor device further includes a second dielectric layer over the first dielectric layer, the gate structure, and the source/drain region, the second dielectric layer having a dielectric constant less than 3.5. In an embodiment, the second dielectric layer has a first density of Si—CH₃ bonds, the second dielectric layer has a second density of Si—O bonds, and a ratio of the first density to the second density is in a range of 50% to 120%. In an embodiment, the second dielectric layer includes boron nitride.

Advantageous features of some embodiments disclosed herein include a method for manufacturing a semiconductor device, the method comprising forming a dummy gate over a semiconductor fin, forming a source/drain region on the semiconductor fin, the source/drain region being adjacent to the dummy gate, using diethoxymethylsilane and alpha-Terpinene as precursors to deposit a first dielectric layer over the dummy gate and the source/drain region, the first dielectric layer having a dielectric constant less than 3.5, and after depositing the first dielectric layer, forming a first opening by removing the dummy gate.

Advantageous features of other embodiments disclosed herein my include a semiconductor device comprising a fin extending from a substrate, a gate structure over the fin, a source/drain region adjacent the gate structure, and a first dielectric layer over the fin, the first dielectric layer having a dielectric constant of 3.5 or less, the first dielectric layer comprising boron nitride, the first dielectric layer extending below a top surface of the gate structure.

Advantageous features of yet other embodiments disclosed herein include a method for forming a semiconductor device, the method comprising forming a dummy gate over a semiconductor fin, forming a source/drain region on the semiconductor fin, the source/drain region being adjacent to the dummy gate, and depositing a first dielectric layer over the dummy gate and the source/drain region using a plasma deposition process with an oxygen-containing precursor gas and a hydrocarbon-containing precursor gas to form the first dielectric layer with a dielectric constant of from 2.0 to 3.5. The method further includes forming a first opening in the first dielectric layer by removing the dummy gate, and filling the first opening with a metal gate electrode

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, the method comprising:
forming a dummy gate over a semiconductor fin;
forming a source/drain region on the semiconductor fin, the source/drain region being adjacent to the dummy gate;
using diethoxymethylsilane and alpha-Terpinene as precursors to deposit a first dielectric layer over the dummy gate and the source/drain region, the first dielectric layer having a dielectric constant less than 3.5; and
after depositing the first dielectric layer, forming a first opening by removing the dummy gate.

2. The method of claim 1, further comprising:
depositing a gate structure in the first opening;
forming a second dielectric layer over the gate structure and the first dielectric layer;
forming a second opening through the second dielectric layer and the first dielectric layer to the source/drain region; and
filling the second opening with a source/drain contact.

3. The method of claim 2, wherein the second dielectric layer has a dielectric constant of 3.5 or less.

4. The method of claim 2, wherein the second dielectric layer has a dielectric constant of 3.9 or greater.

5. The method of claim 2, wherein forming the second dielectric layer comprises using diethoxymethylsilane and alpha-Terpinene as precursors.

6. The method of claim 2, wherein forming the second dielectric layer comprises using borazine or boron trichloride as a process gas.

7. The method of claim 2, wherein forming the second opening further comprises removing the second dielectric layer.

8. The method of claim 2, further comprising forming an etch stop layer over the source/drain contact, the second dielectric layer, and the gate structure.

9. A semiconductor device comprising:
a fin extending from a substrate;
a gate structure over the fin;
a source/drain region adjacent the gate structure; and
a first dielectric layer over the fin, the first dielectric layer having a dielectric constant of 3.5 or less, the first dielectric layer comprising boron nitride, the first dielectric layer extending below a top surface of the gate structure.

10. The semiconductor device of claim 9, further comprising a second dielectric layer over the first dielectric layer, the gate structure, and the source/drain region, the second dielectric layer having a dielectric constant less than 3.5.

11. The semiconductor device of claim 10, wherein the second dielectric layer has a first density of Si—CH₃ bonds, the second dielectric layer has a second density of Si—O bonds, and a ratio of the first density to the second density is in a range of 50% to 120%.

12. The semiconductor device of claim 10, wherein the second dielectric layer comprises boron nitride.

13. A method for forming a semiconductor device, the method comprising:
forming a dummy gate over a semiconductor fin;
forming a source/drain region on the semiconductor fin, the source/drain region being adjacent to the dummy gate;
depositing a first dielectric layer over the dummy gate and the source/drain region using a plasma deposition process with an oxygen-containing precursor gas and a hydrocarbon-containing precursor gas to form the first dielectric layer with a dielectric constant of from 2.0 to 3.5;
forming a first opening in the first dielectric layer by removing the dummy gate; and
filling the first opening with a metal gate electrode.

14. The method of claim 13, wherein the plasma deposition process is characterized by an absence of an O₂ precursor gas.

15. The method of claim 13, wherein the oxygen-containing precursor gas is selected from the group consisting of diethoxymethylsilane SiH(CH₃)(OC₂H₅)₂) and TEOS (tetraethylorthosilicate Si(OC₂H₅)₄).

16. The method of claim 13, wherein the hydrocarbon-containing precursor gas is selected from the group consisting of ATRP (alpha-Terpinene C₁₀H₁₆), propane C₃H₈, BCHD (bicycloheptadiene C₇H₈), and C₆H₁₀(C₂H₅)₂).

17. The method of claim 13, wherein the step of depositing a first dielectric layer deposits silicon oxide having Si—CH₃ bonds therein.

18. The method of claim 15, wherein a ratio of a density of Si—CH₃ bonds to a density of Si—O bonds in the first dielectric layer is in a range of 50% to 120%.

19. The method of claim 1, wherein the first dielectric layer has a dielectric constant of between 2.0 and 3.5.

20. The method of claim 1, wherein the step of depositing a first dielectric layer deposits silicon oxide having Si—CH₃ bonds therein, and wherein a ratio of a density of Si—CH₃ bonds to a density of Si—O bonds in the first dielectric layer is in a range of 50% to 120%.
